(19) United States
(12) Patent Application Publication
(10) Pub. No.: US 2026/0262498 A1
(43) Pub. Date: Sep. 3, 2026

(54) SEMICONDUCTOR DEVICE AND ELECTRONIC DEVICE

(71) Applicant: SONY SEMICONDUCTOR SOLUTIONS CORPORATION, KANAGAWA (JP)

(72) Inventor: TATSUMASA HIRATSUKA, KANAGAWA (JP)

(21) Appl. No.: 18/713,732

(22) PCT Filed: Oct. 13, 2022
(86) PCT No.: PCT/JP2022/038242

§ 371 Date: May 28, 2024

(30) Foreign Application Priority Data
Dec. 2, 2021 (JP) 2021-196104

(51) Int. Cl. H10W 42/00; H10F 39/00; H10W 40/20; H10W 90/00

(52) U.S. Cl. CPC H10W 42/121; H10F 39/809; H10W 40/20; H10W 90/792

(57) ABSTRACT

The semiconductor device according to the present technology includes: at least one first element substrate; at least one second element substrate laminated with the first element substrate and smaller than the first element substrate; and a filling layer filling in at least a periphery of the second element substrate, wherein at least a part of an end portion of the second element substrate on the first element substrate side is a thermal expansion suppression portion, and/or the thermal expansion suppression portion is provided directly or indirectly on an end surface of the part. According to the semiconductor device of the present technology, a property fluctuation of an element of the first element substrate can be suppressed.

### TECHNICAL FIELD

The technology of the present disclosure (also referred to as the present technology, hereinafter) relates to a semiconductor device and an electronic device.

### Background Art

There has been conventionally known a semiconductor device that has a first element substrate, a second element substrate laminated with the first element substrate and smaller than the first element substrate, and a filling layer filling in the periphery of the second element substrate (see PTL 1, for example).

### CITATION LIST

### Patent Literature

PTL 1

WO 2019/087764

### SUMMARY

### Technical Problem

The conventional semiconductor device has room for improvement in suppressing a property fluctuation of an element of the first element substrate.

Therefore, the main object of the present technology is to provide a semiconductor device capable of suppressing a property fluctuation of an element of the first element substrate.

### Solution to Problem

The present technology provides a semiconductor device comprising at least one first element substrate, at least one second element substrate laminated with the first element substrate and smaller than the first element substrate, and a filling layer filling in at least a periphery of the second element substrate, wherein at least a part of an end portion of the second element substrate on the first element substrate side is a thermal expansion suppression portion, and/or the thermal expansion suppression portion is provided directly or indirectly on an end surface of the part.

The first element substrate may include a first semiconductor substrate and a first wiring layer laminated together, the second element substrate may include a second semiconductor substrate and a second wiring layer laminated together, and the first and second element substrates may be bonded to each other in such a manner that the first and second wiring layers face each other.

The thermal expansion suppression portion may be provided directly or indirectly at least on an end surface of the second wiring layer out of end surfaces of the second semiconductor substrate and the second wiring layer.

The thermal expansion suppression portion may have a lower thermal expansion coefficient than the second wiring layer.

The thermal expansion suppression portion may have a lower thermal expansion coefficient than the second semiconductor substrate.

The second semiconductor substrate may be a silicon substrate.

The thermal expansion suppression portion may be made of an inorganic material or an organic material.

The thermal expansion suppression portion may have rounded corners.

The thermal expansion suppression portion may be at least a part of an end portion of the second wiring layer on the first element substrate side.

The width of the thermal expansion suppression portion in an in-plane direction may be 100 μm or more.

The semiconductor device may further include a protective film provided between the filling layer and a set of the first wiring layer, the second wiring layer, and the second semiconductor substrate.

The protective film may be made of SiN.

The semiconductor device may further include a heat dissipation member bonded to a surface of the filling layer that is opposite to the first element substrate side.

The heat dissipation member may contain any of SiC, AIN, SiN, Cu, Al, and C.

The at least one second element substrate may be a plurality of second element substrates.

The semiconductor device according to claim 1, wherein the at least one first element substrate is a plurality of the first element substrates that are laminated.

The first element substrate may include a pixel portion having a photoelectric conversion element, and the second element substrate may process a signal output from the pixel portion.

The second element substrate may include any of a memory element, a logic element, an analog element, an interface element, and an AI element.

The present technology also provides an electronic device having the semiconductor device.

### BRIEF DESCRIPTION OF DRAWINGS

FIG. 1 is a diagram for explaining the background of the present technology.

FIGS. 2A to 2G are each a diagram showing an example of a process for manufacturing a conventional semiconductor device having a two-layer structure.

FIGS. 3A to 3H are each a diagram showing an example of a process for manufacturing a conventional semiconductor device having a three-layer structure.

FIG. 4 is a diagram for explaining a cause of a property fluctuation in a transistor in the conventional semiconductor device having a two-layer structure.

FIG. 5A is a vertical cross-sectional view of the conventional semiconductor device having a three-layer structure. FIG. 5B is a graph showing the relationship between the position of a chip in an in-plane direction and a change in mobility of a Mid layer.

FIGS. 6A to 6D are each a diagram showing a process for manufacturing a semiconductor device in which a distortion occurs.

FIG. 7 is a diagram showing the relationship between the position of a chip in the in-plane direction and a stress occurring in the chip in each of the steps shown in FIGS. 6A to 6D.

FIG. 8A is a diagram schematically showing a mid layer, a bottom wiring layer, and a bottom Si substrate prior to a temperature rise in a conventional semiconductor device. FIG. 8B is a diagram schematically showing the mid layer, the bottom wiring layer, and the bottom Si substrate during a temperature rise in the conventional semiconductor substrate.

FIG. 9A is a diagram schematically showing the mid layer, the bottom wiring layer, and the bottom Si substrate during a temperature rise in the conventional semiconductor device. FIG. 9B is a diagram showing Configuration Example 1 of the present technology. FIG. 9C is a diagram showing Configuration Example 2 of the present technology.

FIG. 10A is a vertical cross-sectional view of a semiconductor device according to Example 1 of an embodiment of the present technology. FIG. 10B is a lateral cross-sectional view of the semiconductor device according to Example 1 of an embodiment of the present technology.

FIG. 11 is a flowchart for explaining an example of a method of manufacturing the semiconductor device of FIG. 10A.

FIGS. 12A and 12B are each a cross-sectional view of each step of the method of manufacturing the semiconductor device of FIG. 10A.

FIGS. 13A and 13B are each a cross-sectional view of each step of the method of manufacturing the semiconductor device of FIG. 10A.

FIGS. 14A and 14B are each a cross-sectional view of each step of the method of manufacturing the semiconductor device of FIG. 10A.

FIGS. 15A and 15B are each a cross-sectional view of each step of the method of manufacturing the semiconductor device of FIG. 10A.

FIGS. 16A and 16B are each a cross-sectional view of each step of the method of manufacturing the semiconductor device of FIG. 10A.

FIG. 17A is a vertical cross-sectional view of a semiconductor device according to Example 2 of an embodiment of the present technology. FIG. 17B is a lateral cross-sectional view of the semiconductor device according to Example 2 of an embodiment of the present technology.

FIGS. 18A to 18C are each a diagram showing a configuration example of a thermal expansion suppression portion of the semiconductor device of FIG. 17A.

FIG. 19 is a flowchart for explaining an example of a method of manufacturing the semiconductor device of FIG. 17A.

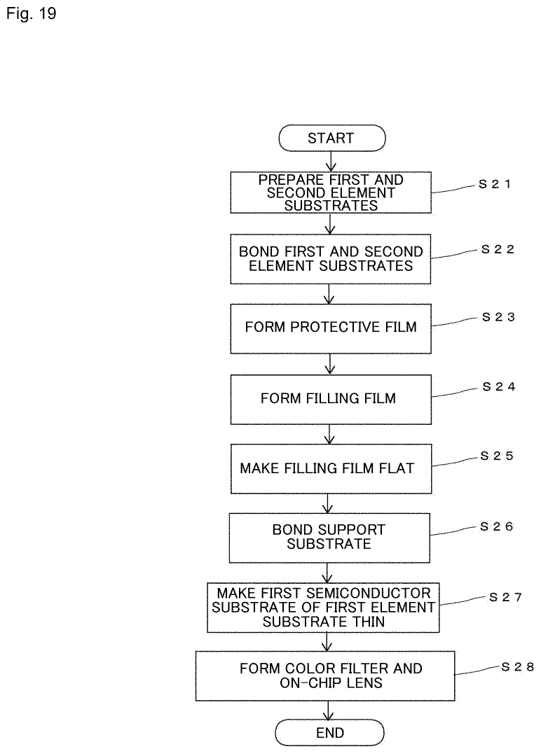

FIGS. 20A and 20B are each a cross-sectional view of each step of the method of manufacturing the semiconductor device of FIG. 17A.

FIGS. 21A and 21B are each a cross-sectional view of each step of the method of manufacturing the semiconductor device of FIG. 17A.

FIGS. 22A and 22B are each a cross-sectional view of each step of the method of manufacturing the semiconductor device of FIG. 17A.

FIGS. 23A and 23B are each a cross-sectional view of each step of the method of manufacturing the semiconductor device of FIG. 17A.

FIG. 24 is a vertical cross-sectional view of a semiconductor device according to Example 3 of an embodiment of the present technology.

FIG. 25 is a flowchart for explaining a method of manufacturing the semiconductor package of FIG. 24.

FIGS. 26A and 26B are each a cross-sectional view of each step of the method of manufacturing the semiconductor device of FIG. 24.

FIGS. 27A and 27B are each a cross-sectional view of each step of the method of manufacturing the semiconductor device of FIG. 24.

FIG. 28 is a vertical cross-sectional view of a semiconductor device according to Example 4 of an embodiment of the present technology.

FIG. 29 is a vertical cross-sectional view of a semiconductor device according to Example 5 of an embodiment of the present technology.

FIG. 30 is a vertical cross-sectional view of a semiconductor device according to Example 6 of an embodiment of the present technology.

FIG. 31 is a vertical cross-sectional view of a semiconductor device according to Example 7 of an embodiment of the present technology.

FIG. 32 is a vertical cross-sectional view of a semiconductor device according to Example 8 of an embodiment of the present technology.

FIG. 33A is a vertical cross-sectional view of a semiconductor device according to Example 9 of an embodiment of the present technology. FIG. 33B is a lateral cross-sectional view of the semiconductor device according to Example 9 of an embodiment of the present technology.

FIG. 34A is a vertical cross-sectional view (1) of a semiconductor device according to Example 10 of an embodiment of the present technology. FIG. 34B is a vertical cross-sectional view (2) of the semiconductor device according to Example 10 of an embodiment of the present technology. FIG. 34C is a lateral cross-sectional view of the semiconductor device according to Example 10 of an embodiment of the present technology.

FIG. 35 is a vertical cross-sectional view of a semiconductor device according to Example 11 of an embodiment of the present technology.

FIG. 36 is a vertical cross-sectional view of a semiconductor device according to Example 12 of an embodiment of the present technology.

FIG. 37 is a vertical cross-sectional view of a semiconductor device according to Example 13 of an embodiment of the present technology.

FIG. 38 is a vertical cross-sectional view of a semiconductor device according to Example 14 of an embodiment of the present technology.

FIG. 39 is a vertical cross-sectional view of a semiconductor device according to Example 15 of an embodiment of the present technology.

FIG. 40 is a vertical cross-sectional view of a semiconductor device according to Example 16 of an embodiment of the present technology.

FIG. 41 is a vertical cross-sectional view of a semiconductor device according to Example 17 of an embodiment of the present technology.

FIG. 42 is a vertical cross-sectional view of a semiconductor device according to Example 18 of an embodiment of the present technology.

FIG. 43 is a vertical cross-sectional view of a semiconductor device according to Example 19 of an embodiment of the present technology.

FIG. 44 is a vertical cross-sectional view of a semiconductor device according to Example 20 of an embodiment of the present technology.

FIG. 45 is a vertical cross-sectional view of a semiconductor device according to Example 21 of an embodiment of the present technology.

FIG. 46 is a vertical cross-sectional view of a semiconductor device according to Example 22 of an embodiment of the present technology.

FIG. 47 is a vertical cross-sectional view of a semiconductor device according to Example 23 of an embodiment of the present technology.

FIG. 48 is a vertical cross-sectional view of a semiconductor device according to Example 24 of an embodiment of the present technology.

FIG. 49 is a vertical cross-sectional view of a semiconductor device according to Example 25 of an embodiment of the present technology.

FIG. 50 is a diagram showing an example of use of a solid-state imaging device which is an example of the semiconductor device according to the present technology.

FIG. 51 is a functional block diagram of an electronic device provided with the semiconductor device according to the present technology.

FIG. 52 is a block diagram showing an example of a schematic configuration of a vehicle control system.

FIG. 53 is an explanatory diagram showing examples of installation positions of a vehicle exterior information detection unit and an imaging unit.

FIG. 54 is a diagram showing an example of a schematic configuration of an endoscopic surgery system.

FIG. 55 is a block diagram showing examples of functional configurations of a camera head and a CCU.

### DESCRIPTION OF EMBODIMENTS DONE

Preferred embodiments of the present technology will be described hereinafter in detail with reference to the accompanying drawings. In the present specification and the drawings, components having substantially the same functional configuration will be denoted by the same reference numerals, and thus repeated descriptions thereof will be omitted. The embodiments to be described below show representative embodiments of the present technology, and the scope of the present technology should not be narrowly interpreted based on the embodiments. Even in a case where the present specification describes that the semiconductor device according to the present technology exhibits a plurality of advantageous effects, the semiconductor device according to the present technology may exhibit at least one advantageous effect. The advantageous effects described in the present specification are merely exemplary and are not limited, and other advantageous effects may be obtained.

The description will be given in the following order.
0. Introduction
1. Semiconductor device according to Example 1 of an embodiment of the present technology
2. Semiconductor device according to Example 2 of an embodiment of the present technology
3. Semiconductor device according to Example 3 of an embodiment of the present technology
4. Semiconductor device according to Example 4 of an embodiment of the present technology
5. Semiconductor device according to Example 5 of an embodiment of the present technology
6. Semiconductor device according to Example 6 of an embodiment of the present technology
7. Semiconductor device according to Example 7 of an embodiment of the present technology
8. Semiconductor device according to Example 8 of an embodiment of the present technology
9. Semiconductor device according to Example 9 of an embodiment of the present technology
10. Semiconductor device according to Example 10 of an embodiment of the present technology
11. Semiconductor device according to Example 11 of an embodiment of the present technology
12. Semiconductor device according to Example 12 of an embodiment of the present technology
13. Semiconductor device according to Example 13 of an embodiment of the present technology
14. Semiconductor device according to Example 14 of an embodiment of the present technology
15. Semiconductor device according to Example 15 of an embodiment of the present technology
16. Semiconductor device according to Example 16 of an embodiment of the present technology
17. Semiconductor device according to Example 17 of an embodiment of the present technology
18. Semiconductor device according to Example 18 of an embodiment of the present technology
19. Semiconductor device according to Example 19 of an embodiment of the present technology
20. Semiconductor device according to Example 20 of an embodiment of the present technology
21. Semiconductor device according to Example 21 of an embodiment of the present technology
22. Semiconductor device according to Example 22 of an embodiment of the present technology
23. Semiconductor device according to Example 23 of an embodiment of the present technology
24. Semiconductor device according to Example 24 of an embodiment of the present technology
25. Semiconductor device according to Example 25 of an embodiment of the present technology
26. Modifications of the present technology
27. Example of use of an electronic device provided with the semiconductor device according to the present technology
28. Another example of use of the electronic device provided with the semiconductor device according to the present technology
29. Example of application to a mobile object
30. Example of application to an endoscopic surgery system

### 0. Introduction

As a conventional bonding technology that allows for cost reduction of a sensor for a large-format camera and mixture of a plurality of types of logic chips and memory chips, chip-on-wafer (CoW) for bonding a chip directly to a wafer and chip-on-chip (CoC) for bonding a chip directly to a chip have been developed.

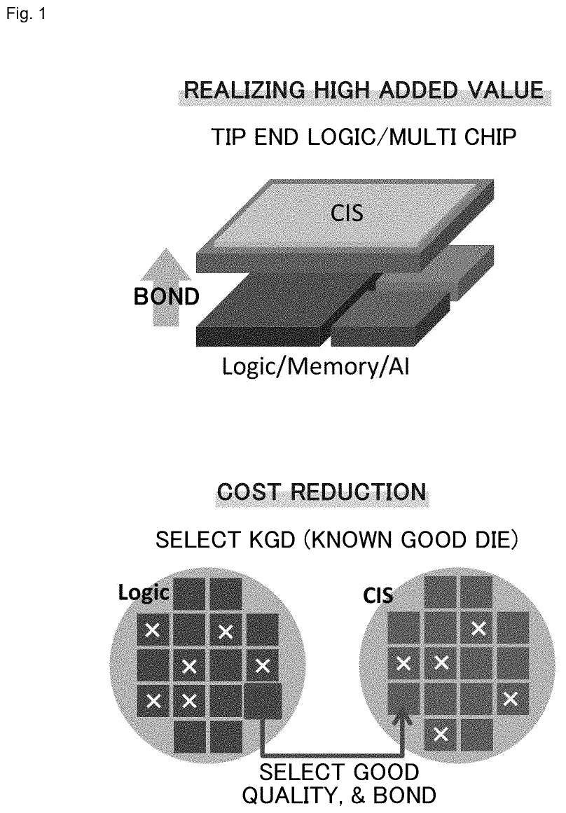

In recent years, in CoW and CoC, for example, a multi-chip bonding technology for bonding a plurality of chips such as logic chips, memory chips, and AI chips directly to a wafer or chip having a CIS (Cmos Image Sensor) formed therein has also been developed (see FIG. 1). The multi-chip bonding technology has attracted attention as a technology for realizing high added value.

In CoW and CoC, by bonding a chip selected as a good-quality product to a wafer or chip selected as a good quality product by means of KGD (Known Good Die), throughput yield and cost reduction can be achieved.

Now, an example of a process for manufacturing a conventional semiconductor device (e.g., solid-state imaging device) having a two-layer structure (e.g., CoW structure) will be simply described.

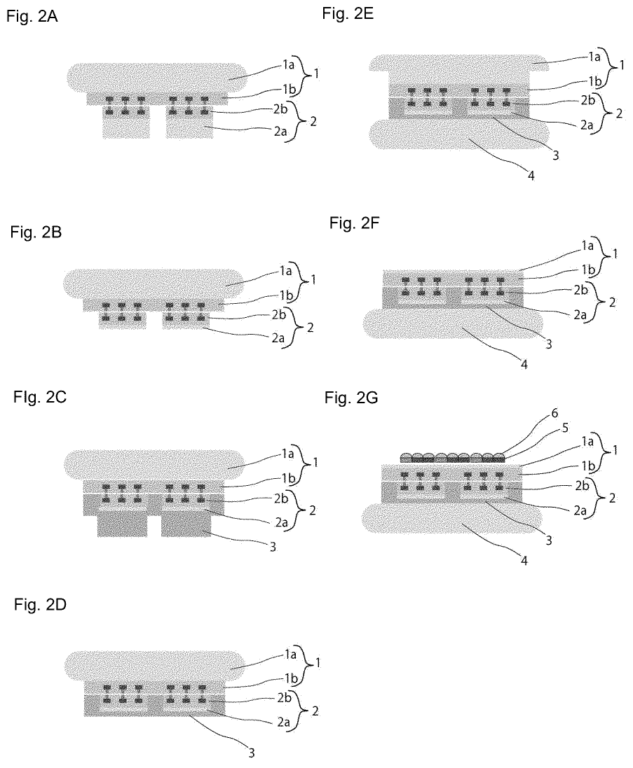

(Step 2A) An element substrate 1 (e.g., CIS substrate) including a semiconductor substrate 1a (e.g., Si substrate) and a wiring layer 1b and an element substrate 2 (e.g., logic substrate, memory substrate, AI substrate, or the like) including a semiconductor substrate 2a and a wiring layer 2b and smaller than the element substrate 1 are bonded to each other in such a manner that the wiring layers 1b, 2b face each other (see FIG. 2A).

(Step 2B) The semiconductor substrate 2a is made thin (see FIG. 2B).

(Step 2C) A filling layer 3 (e.g., SRO film) is formed from the element substrate 2 side (see FIG. 2C).

(Step 2D) The filling layer 3 is made flat (see FIG. 2D).

(Step 2E) A support substrate 4 is bonded to the filling layer 3 (see FIG. 2E).

(Step 2F) The semiconductor substrate 1a is made thin (see FIG. 2F).

((Step 2G) A color filter 5 and an on-chip lens 6 are formed on the semiconductor substrate 1a (see FIG. 2G).

Next, an example of a process for manufacturing a conventional semiconductor device (e.g., solid-state imaging device) having a three-layer structure (e.g., composite structure with WoW and CoW) will be simply described.

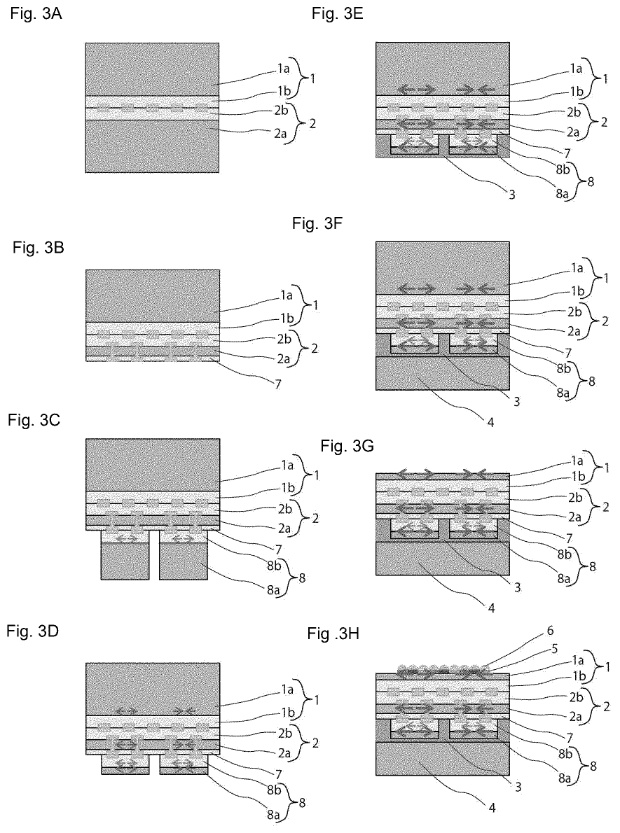

(Step 3A) The element substrate 1 (top layer: e.g., CIS substrate) including the semiconductor substrate 1a (e.g., Si substrate) and the wiring layer 1b and the element substrate 2 (mid layer: e.g., analog substrate) including the semiconductor substrate 2a and the wiring layer 2b are bonded directly to each by WoW (see FIG. 3A).

(Step 3B) After making the semiconductor substrate 2 a thin, a through electrode that penetrates the semiconductor substrate 2a and has one end electrically connected to the wiring layer 2b and the other end exposed on a rear surface of the semiconductor substrate 2a is formed, and a wiring layer 7 that is electrically connected to the other end of the through electrode is formed on the rear surface of the semiconductor substrate 2a (see FIG. 3B).

(Step 3C) An element substrate 8 (bottom chip: e.g., logic substrate, memory substrate, AI substrate, or the like) including a semiconductor substrate 8a and a wiring layer 8b and the wiring layer 7 are bonded directly to each other by CoW (see FIG. 3C).

(Step 3D) The semiconductor substrate 8 a is made thin (FIG. 3D).

(Step 3E) The filling layer 3 (e.g., SRO film) is formed from the element substrate 8 side and made flat (see FIG. 3E).

(Step 3F) A support substrate 4 is bonded to the filling layer 3 (see FIG. 3F).

(Step 3G) The semiconductor substrate 1a is made thin (see FIG. 3G).

(Step 3H) The color filter 5 and the on-chip lens 6 are formed on the semiconductor substrate 1a (see FIG. 3H).

In the aforementioned step 3C, a distortion occurs due to bonding (see the arrows in FIG. 3C). In the aforementioned step 3D, a distortion occurs due to polishing (see the arrows in FIG. 3D). In the aforementioned step 3E, a distortion occurs due to burying (see the arrows in FIG. 3E). In the aforementioned step 3F, a distortion occurs due to bonding (see the arrows in FIG. 3F). In the aforementioned step 3G, a distortion occurs due to polishing (see the arrows in FIG. 3G). In the aforementioned step 3H, the on-chip lens and the like are misaligned due to the effect of the distortion that has occurred in the previous step, and the misalignment affects the optical properties.

The same distortion occurs in the aforementioned steps 2A, 2B, 2C, 2E, and 2F. In the aforementioned step 2G, the on-chip lens and the like are misaligned due to the effect of the distortion that has occurred in the previous step, and the misalignment affects the optical properties.

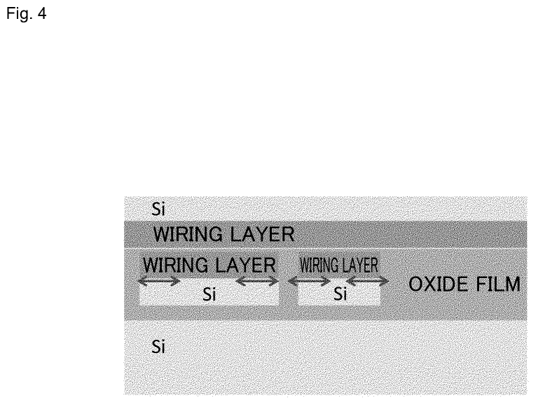

A particularly significant problems in terms of device characteristics is that the distortion caused by burying in the aforementioned steps 2C and 3E cannot be relieved, and the properties of the transistor formed on the Si substrate fluctuate (see FIG. 4). The property fluctuation of the transistor leads to reduced throughput yield or reduced reliability.

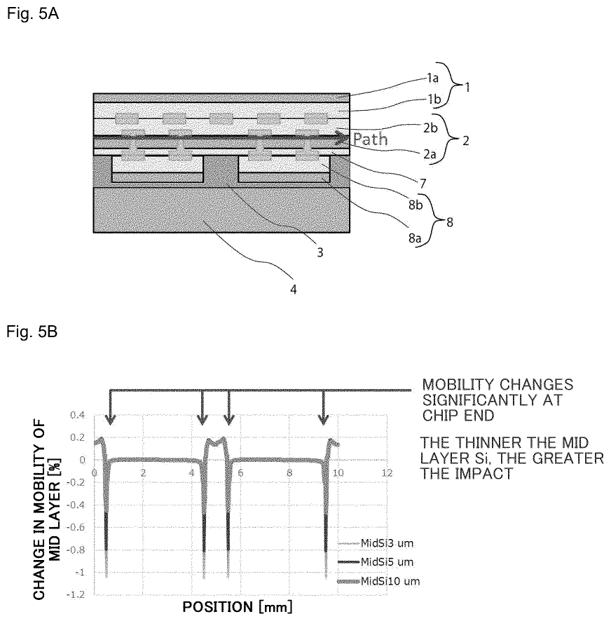

Taking the semiconductor device having a three-layer structure (see FIG. 5A) as an example, it was found out that distortion of the element substrate 8 (bottom chip) caused during the manufacturing process causes a distortion in the semiconductor substrate 2a of the element substrate 2 (mid layer) and causes a local property fluctuation. After calculating the mobility of the mid layer on the path of the transistor (see FIG. 5B), it was found out that the mobility of the element substrate 2 changes significantly at a position near a chip end of the element substrate 8 due to a distortion of the chip end. It was also found out that the thinner the semiconductor substrate 2a of the element substrate 2 (mid layer) is, the more significant this change in mobility becomes (see FIG. 5B).

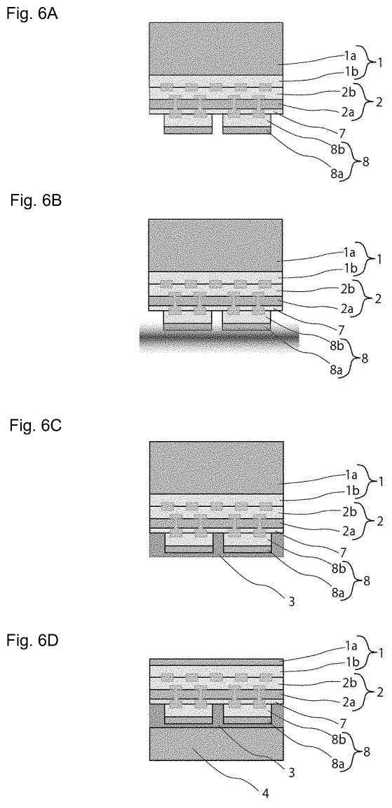

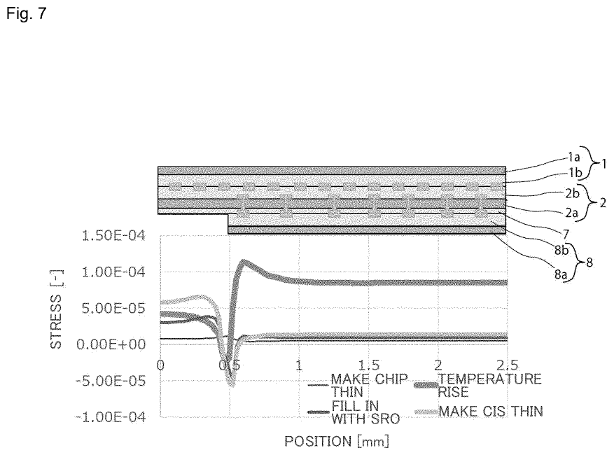

As a result of measuring the stress within the element substrate 8 in each of a chip thinning step (see FIG. 6A), a temperature rise step (see FIG. 6B), a burying step (see FIG. 6C), and a support substrate bonding/CIS substrate thinning step (see FIG. 6D) that cause a distortion in the chip end of the element substrate 8, it was found out that the stress changes significantly particularly at the chip end of the element substrate 8 (see FIG. 7).

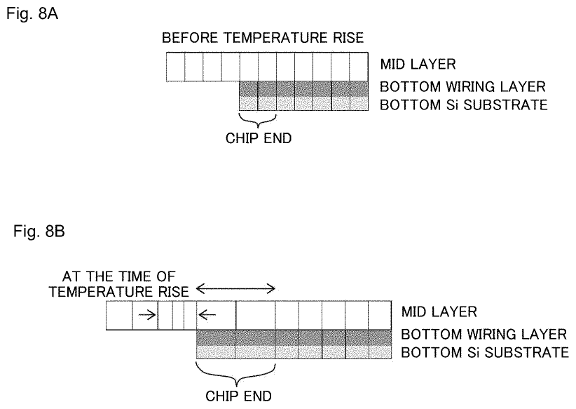

This is because the chip end of the mid layer is fixed by the filling layer during the burying step in a state where the chip end of the bottom layer (bottom wiring layer and bottom Si substrate) is stretched and the sides of the chip end of the mid layer shrink (see FIG. 8B) due to thermal expansion during the temperature rise step in contrast to the state prior to the temperature rise step (see FIG. 8A).

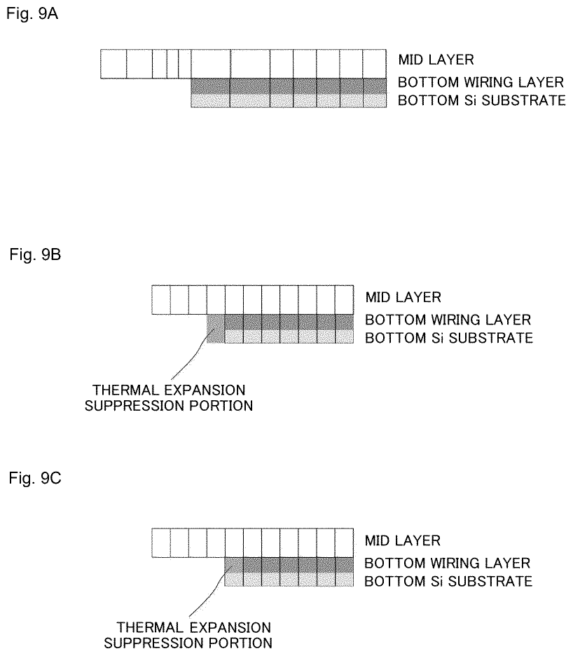

From the above consideration, the inventors have discovered that it is possible to suppress thermal expansion of a part, which is essentially the chip end, to prevent the sides of the chip end of the mid layer from shrinking by providing the thermal expansion suppression portion in, for example, the chip end (see FIG. 9B) or causing, for example, the chip end as the thermal expansion suppression portion (see FIG. 9C), with respect to the bottom chip of the conventional semiconductor device (see FIG. 9A), and have developed the semiconductor device according to the present technology based on this discovery.

Hereinafter, an embodiment of the present technology will be described in detail with reference to several examples.

### 1. Semiconductor Device According to Example 1 of an Embodiment of the Present Technology

Hereinafter, a semiconductor device 10 according to Example 1 of an embodiment of the present technology will be described with reference to the drawings.

### Configuration of Semiconductor Device

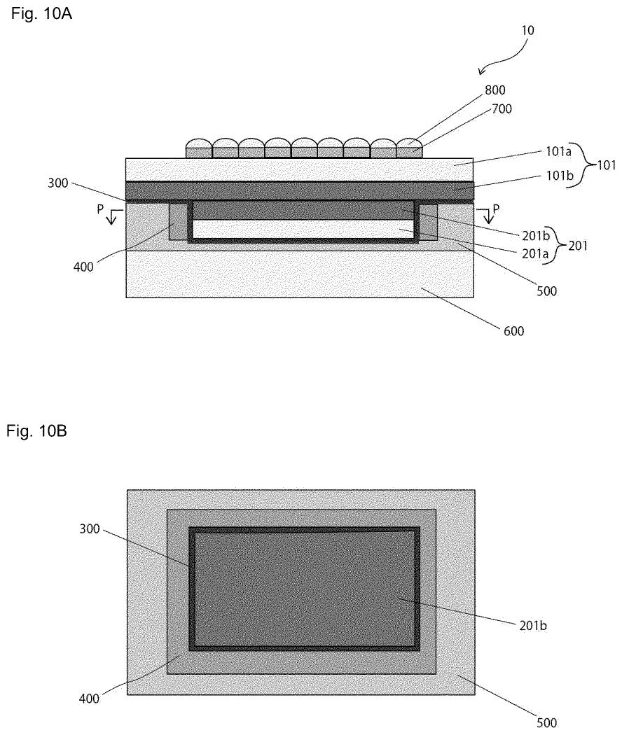

FIG. 10A is a vertical cross-sectional view of the semiconductor device 10 according to Example 1 of an embodiment of the present technology. FIG. 10B is a lateral cross-sectional view of the semiconductor device 10 according to Example 1 of an embodiment of the present technology. Specifically, FIG. 10B is a cross-sectional view taken along P-P of FIG. 10A. Hereinafter, for convenience, the upper side is described as top and the lower side as bottom in the cross-sectional views such as FIG. 10A.

The semiconductor device 10 constitutes a solid-state imaging device, as an example. The semiconductor device 10 is, as an example, a rear surface irradiation type solid-state imaging device in which light is emitted from a rear surface side of a first semiconductor substrate 101a described later.

The semiconductor device 10 is, as an example, a semiconductor device with a two-layer structure (CoW). Specifically, as an example, as shown in FIG. 10A and FIG. 10B, the semiconductor device 10 includes a first element substrate 101, at least one (e.g., one) second element substrate 201 laminated with the first element substrate 101 and smaller than the first element substrate 101, and a filling layer 500 filling in the periphery of at least the second element substrate 201. A thermal expansion suppression portion 400 is provided indirectly on an end surface of an end portion of the second element substrate 201.

The semiconductor device 10 also includes, as an example, a support substrate 600 (e.g., a silicon substrate) bonded to a surface of the filling layer 500 that is opposite (lower side) to the first element substrate 101 side. As an example, the support substrate 600 is bonded to the filling layer 500 by oxide film bonding.

The first element substrate 101 has the first semiconductor substrate 101a and a first wiring layer 101b laminated together, and the second element substrate 201 has a second semiconductor substrate 201a and a second wiring layer 201b laminated together. The first and second element substrates 101 and 201 are bonded directly to each other by, for example, metal bonding in such a manner that the first and second wiring layers 101b and 201b face each other.

The semiconductor device 10 further includes a protective film 300 provided between the set of the first wiring layer 101b, the second wiring layer 201b, and the second semiconductor substrate 201a, and the filling layer 500.

### Protective Film

The protective film 300 is formed of an inorganic film such as a SiN-based (e.g., SiN) inorganic film, and functions not only as a metal diffusion prevention film for preventing diffusion of a metal from the first and second wiring layers 101b and 201b, but also as a foreign matter entry prevention layer for preventing foreign matter such as moisture and dust from entering the first and second element substrates 101 and 201. The protective film 300 is provided along the first and second wiring layers 101b and 201b and the second semiconductor substrate 201a. The thickness of the protective film 300 is, for example, approximately several hundred nm. Note that the protective film 300 may be formed of, for example, a SiO-based (e.g., SiOx), SiON-based, SiCN-based, or SiOC-based inorganic film.

### Filling Layer

The filling layer 500 is provided on, as an example, an end surface side and a rear surface side of a structure including the second element substrate 201, the protective film 300, and the thermal expansion suppression portion 400. A lower surface of the filling layer 500 is a substantially uniform flat surface. It is preferred that the filling layer 500 be formed of an inorganic oxide film or an organic film. Examples of the material of the inorganic film for the filling layer 500 include SiN-based (e.g., SiNx), SiO-based (e.g., SiOx), SiON-based, SiCN-based, and SiOC-based materials.

### First Element Substrate

In the first element substrate 101, as an example, a pixel portion is provided in the first semiconductor substrate 101a. The pixel portion has, as an example, a plurality of two-dimensionally arranged pixels. Each of the pixels has at least one photoelectric conversion element. The photoelectric conversion element is, for example, a PD (photodiode). Each of the pixels has a color filter 700 on a rear surface of the first semiconductor substrate 101a (the surface opposite to the first wiring layer 101b), and an on-chip lens 800 (microlens) on the color filter 700. That is, each pixel is a rear surface irradiation type pixel in which light is emitted from the rear surface side of the semiconductor substrate 101a.

In the first element substrate 101, as an example, the first semiconductor substrate 101a is disposed on the first wiring layer 101b. In the first element substrate 101, as an example, the vertical cross-sectional shapes of both the first semiconductor substrate 101a and the first wiring layer 101b are a rectangular shape, and the entire first element substrate 101 has a rectangular vertical cross-sectional shape.

The first semiconductor substrate 101a is electrically connected to the first wiring layer 101b. The first semiconductor substrate 101a is, for example, a Si substrate, a Ge substrate, a GaAs substrate, InGaAs substrate, or the like.

The first wiring layer 101b may be a multi-layer wiring layer in which multiple layers of internal wiring are provided within an insulating film, or a single-layer wiring layer in which a single layer of internal wiring is provided within an insulating film. In the first wiring layer 101b, the internal wiring is composed of, for example, Cu, Al, W, Au, Co, Ta, Ti or the like, and the insulating film is composed of, for example, a silicon oxide film, silicon nitride film, or the like.

Furthermore, in the first semiconductor substrate 101a, as an example, a control circuit (analog element) for controlling the plurality of pixels, and an A/D converter (analog element) for A/D-converting an electrical signal (analog signal) output from the pixel portion.

The control circuit has a circuit element such as a transistor. Specifically, as an example, the control circuit includes a plurality of pixel transistors (so-called MOS transistors). For example, the plurality of pixel transistors may be constituted of three transistors: a transfer transistor, a reset transistor, and an amplifier transistor. Alternatively, the plurality of pixel transistors may be constituted of four transistors further including a selection transistor. Since an equivalent circuit of a unit pixel is the same as usual, a detailed description thereof will be omitted. The pixels can be configured as one unit pixel. The pixels can also have a shared pixel structure. The pixel shared structure is a structure in which a plurality of photodiodes share floating diffusion constituting the transfer transistor, and the transistors other than the transfer transistor.

### Second Element Substrate

The second element substrate 201 includes, as an example, a logic element for processing a signal output from the pixel portion. The second element substrate 201 may include any of, for example, a memory element, an analog element (e.g., the aforementioned control circuit, A/D converter, etc.), an interface element, and an AI element. Note that the interface element is an element for inputting/outputting signals. The AI element is an element having an AI-based (artificial intelligence) learning function.

In the second element substrate 201, as an example, a logic circuit is provided in the second semiconductor substrate 201a, and this logic circuit is electrically connected to the second wiring layer 201b. The logic circuit includes a transistor, and processes a digital signal that is obtained as a result of the A/D converter performing A/D conversion on an analog signal output from the pixel portion.

In the second element substrate 201, as an example, the second wiring layer 201b is disposed on the second semiconductor substrate 201a. In the second element substrate 201, as an example, the vertical cross-sectional shapes of both the second semiconductor substrate 201a and the second wiring layer 201b are a rectangular shape, and the entire second element substrate 201 has a rectangular vertical cross-sectional shape.

The second semiconductor substrate 201a is, for example, a Si substrate, a Ge substrate, a GaAs substrate, InGaAs substrate, or the like.

The second wiring layer 201b may be a multi-layer wiring layer in which multiple layers of internal wiring are provided within an insulating film, or a single-layer wiring layer in which a single layer of internal wiring is provided within an insulating film. In the second wiring layer 201b, the internal wiring is composed of, for example, Cu, Al, W, Au, Co, Ta, Ti or the like, and the insulating film is composed of, for example, a silicon oxide film, silicon nitride film, or the like.

### Thermal Expansion Suppression Portion

The thermal expansion suppression portion 400 is provided on an end surface of the second element substrate 201 (an end surface the second semiconductor substrate 201a and an end surface of the second wiring layer 201b) via the protective film 300 (indirectly). The thermal expansion suppression portion 400 is provided in the shape of a frame (e.g., a rectangular shape) so as to surround the second element substrate 201 via the protective film 300 (see FIG. 10B).

It is preferred that the thermal expansion suppression portion 400 have a lower thermal expansion coefficient (linear expansion coefficient) than the second wiring layer 201b and have a lower thermal expansion coefficient than the second semiconductor substrate 201a. Note that in general, the linear expansion coefficient of the material of the wiring layers (insulating film and internal wiring) is higher than that of the material of the semiconductor substrates (e.g., Si).

It is preferred that the thermal expansion suppression portion 400 be made of an inorganic material or an organic material. Examples of the inorganic material include SiN-based (e.g., SiNx), SiO-based (e.g., SiOx), SiON-based, SiCN-based, and SiOC-based materials.

### Operations of Semiconductor Device

Operations of the semiconductor device 10 according to Example 1 of an embodiment of the present technology will be described below.

When light is incident on the pixel portion of the first element substrate 101, analog signals, which are electrical signals obtained by photoelectric conversion of the light, are output. The analog signals are converted into digital signals by the A/D converter, which are then transferred sequentially to the logic circuit of the second element substrate 201. The logic circuit processes the transferred digital signals.

### Method of Manufacturing Semiconductor Device

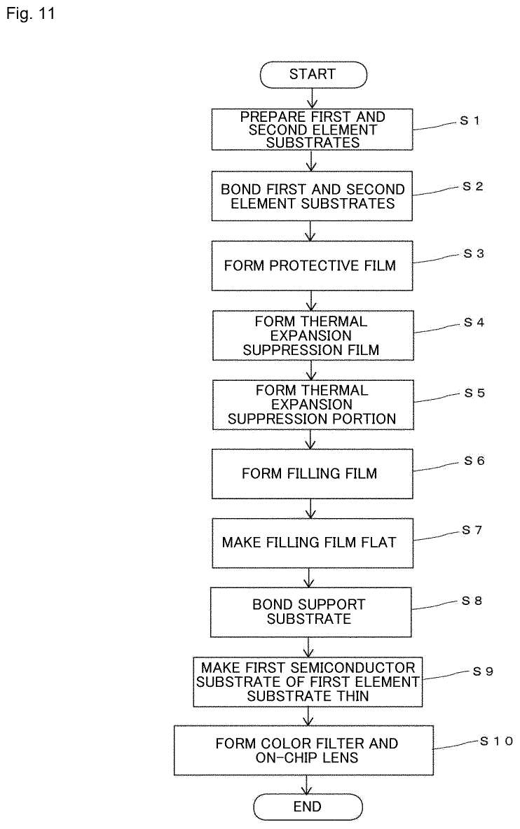

A method of manufacturing the semiconductor device 10 according to Example 1 of an embodiment of the present technology will be described hereinafter with reference to the flowchart of FIG. 11 and FIGS. 12A to 16B.

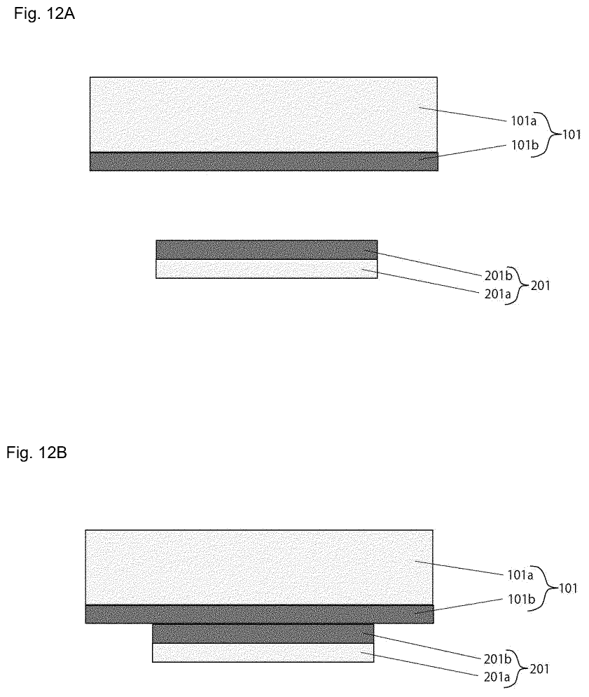

In the first step S1, the first and second element substrates 101 and 201 are prepared (see FIG. 12A). Specifically, the first element substrate 101 is generated by forming an element (e.g., pixel portion) in the first semiconductor substrate 101a and forming the first wiring layer 101b on the first semiconductor substrate 101a by means of photolithography. The second element substrate 201 is generated by forming an element (e.g., logic element) in the second semiconductor substrate 201a and forming the second wiring layer 201b on the second semiconductor substrate 201a by means of photolithography.

In the next step S2, the first and second element substrates 101 and 201 are bonded (see FIG. 12B). Specifically, the first and second element substrates 101 and 201 are bonded by means of, for example, metal bonding, in such a manner that the first wiring layer 101b of the first element substrate 101 and the second wiring layer 201b of the second element substrate 201 face each other.

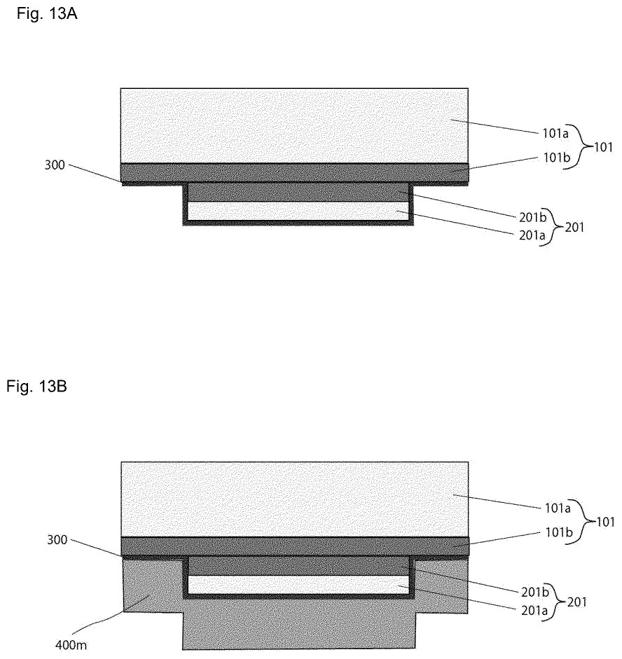

In the next step S3, the protective film 300 is formed (see FIG. 13A). Specifically, the protective film 300 (e.g., SiN film) is thinly formed so as to cover the exposed surfaces of the first and second wiring layers 101b and 201b and the second semiconductor substrate 201a.

In the next step S4, a thermal expansion suppression film 400m is formed (see FIG. 13B). Specifically, the thermal expansion suppression film 400m serving as the thermal expansion suppression portion 400 is formed thick so as to cover the protective film 300.

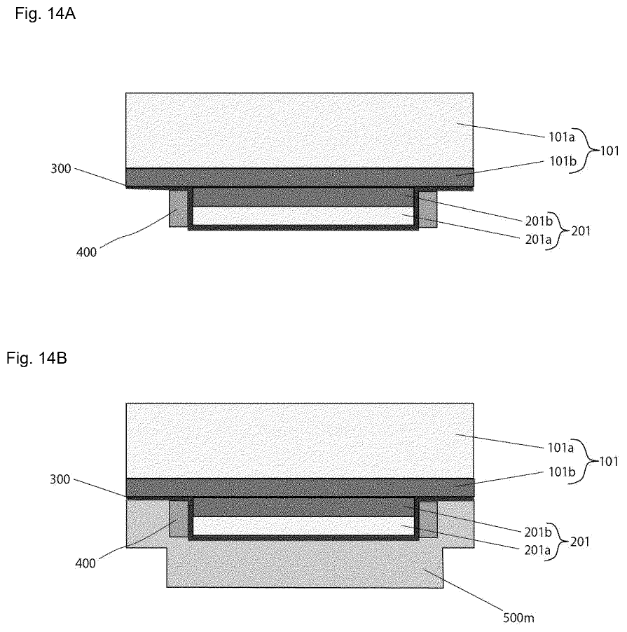

In the next step S5, the thermal expansion suppression portion 400 is formed (see FIG. 14A). Specifically, first, the thermal expansion suppression film 400m is polished and made flat by using, for example, a CMP (Chemical Mechanical Polisher) device. In this case, the protective film 300 functions as a polishing stop layer. Next, the thermal expansion suppression film 400m is etched to leave only the thermal expansion suppression portion 400. In this case, the protective film 300 functions as an etching stop layer.

In the next step S6, a filling film 500m is formed (see FIG. 14B). Specifically, the filling film 500m (e.g., inorganic film or organic film) serving as the filling layer 500 is formed thick over the entire surface. More specifically, the filling film 500m is formed so as to fill in the end surface side and rear surface side of the second element substrate 201 where the thermal expansion suppression portion 400 is provided on the end surface of the second element substrate 201 via the protective film 300.

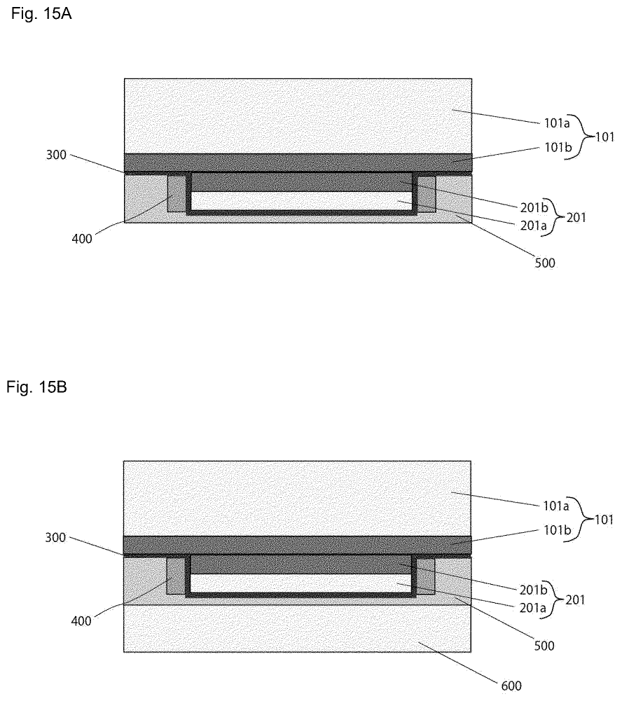

In the next step S7, the filling film 500m is made flat (see FIG. 15A). Specifically, the filling film 500m is polished using, for example, the CMP device (see FIG. 14B) until there is no unevenness. As a result, a uniformly flat filling layer 500 is generated.

In the next step S8, the support substrate 600 is bonded (see FIG. 15B). Specifically, the support substrate 600 is bonded to a rear surface of the filling layer 500 by, for example, oxide film bonding.

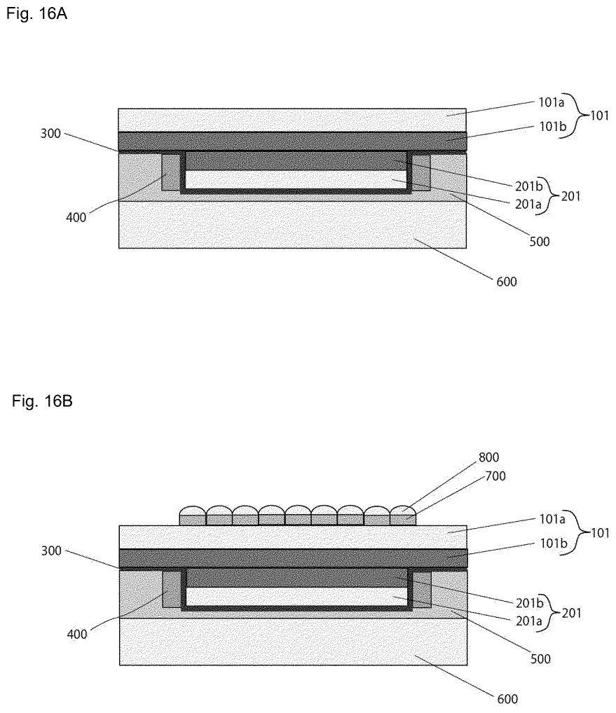

In the next step S9, the first semiconductor substrate 101a of the first element substrate 101 is made thin (see FIG. 16A). Specifically, the rear surface of the first semiconductor substrate 101a (upper surface) is polished and made thin into a desired thickness by using, for example, the CMP device.

In the final step S10, the color filter 700 and the on-chip lens 800 are formed (see FIG. 16B). Specifically, the color filter 700 and the on-chip lens 800 are sequentially formed on the rear surface side of the first semiconductor substrate 101a.

### Advantageous Effects of Semiconductor Device

Advantageous effects of the semiconductor device 10 according to Example 1 of an embodiment of the present technology will be described below.

The semiconductor device 10 according to Example 1 of an embodiment of the present technology has at least one first element substrate 101, at least one second element substrate 201 laminated with the first element substrate 101 and smaller than the first element substrate 101, and the filling layer 500 filling in at least the periphery of the second element substrate 201, wherein the thermal expansion suppression portion 400 is provided indirectly on the end surface of at least a part of the end portion of the second element substrate 201 on the first element substrate 101 side.

In this case, the thermal expansion suppression portion 400 is a substantial end portion (chip end) of the second element substrate 201. As a result, according to the semiconductor device 10, the semiconductor device 10 capable of suppressing a property fluctuation of an element of the first element substrate 101 can be provided.

Here, the mechanism in which stress acts on the chip end of the chip (second element substrate) due to filling lies in the fact that the chip, which has been stretched as a result of a temperature increase when forming the filling film, is fixed by the filling film and the elongation of the chip cannot be alleviated when cooling to a normal temperature. Thus, by making the substantial chip end serve as the thermal expansion suppression portion made of a material for suppressing thermal expansion, “stretching of the chip end due to a temperature increase,” which is the fundamental cause, can be suppressed, thereby preventing the occurrence of stress at the substantial chip end. Accordingly, since a unique property fluctuation caused by stress no longer happens in the chip end of the second element substrate or the transistors of the first element substrate, it is not necessary to set a KOZ (Keep Out Zone) in the chip end of the second element substrate or the first element substrate, and a design allowing for the arrangement of the transistors on the entire surface can be realized.

Additionally, in the conventional semiconductor substrate, the bonded chip is filled with the filling film, wherein, in doing so, the chip expands due to a temperature increase, and the chip is fixed by the filling film while the chip is expanded, and the chip cannot be shrunk (is stretched) when the temperature is cooled to a normal temperature, because the chip is fixed. As a result, tensile stress occurs at the chip end, changing the transistor characteristics of the chip end. This can be dealt with by setting the KOZ in a position up to, for example, 100 μm from the chip end or approximately 100 μm directly above the chip end of the semiconductor substrate of the mid layer, and not arranging transistors in the chip end, but this method cannot be used when achieving high-speed communications between chips or arranging circuits including transistors in the chip end.

In the semiconductor device 10, since the expansion of the substantial chip end can be suppressed, the semiconductor substrate is not fixed by the filling film in a distorted manner, so the transistor properties do not fluctuate. Therefore, it is not necessary to set the KOZ in the chip end of the bottom chip or the mid layer or to arrange a dummy transistor, improving the freedom of design.

The first element substrate 101 includes the first semiconductor substrate 101a and the first wiring layer 101b laminated with each other, and the second element substrate 201 includes the second semiconductor substrate 201a and the second wiring layer 201b laminated with each other, wherein the first and second element substrates 101 and 201 are bonded to each other in such a manner that the first and second wiring layers 101b and 201b face each other.

The thermal expansion suppression portion 400 is provided indirectly in at least the end surface of the second wiring layer 201b out of the end surface of the second semiconductor substrate 201a and the end surface of the second wiring layer 201b. Thus, the thermal expansion suppression portion 400 can be caused to function effectively.

It is preferred that the thermal expansion suppression portion 400 have a lower thermal expansion coefficient than the second wiring layer 201b. Accordingly, an element property fluctuation of the first element substrate 101 can be suppressed effectively.

It is preferred that the thermal expansion suppression portion 400 have a lower thermal expansion coefficient than the second semiconductor substrate 201a. In this case, the second semiconductor substrate 201a may be, for example, a silicon substrate. Accordingly, an element property fluctuation of the first element substrate 101 can be suppressed extremely effectively.

The thermal expansion suppression portion 400 may be made of an inorganic material or an organic material. This improves the freedom of choice of the material suitable for the thermal expansion suppression portion.

It is preferred that the semiconductor device 10 further include the protective film 300 provided between the set of the first wiring layer 101b, the second wiring layer 201b, and the second semiconductor substrate 201a, and the filling layer 500.

It is preferred that the protective film 300 be made of SiN. This can improve the reliability.

It is preferred that the filling layer 500 be formed of an inorganic oxide film or an organic film. This improves the freedom of choice of the material suitable for the filling layer 500.

It is preferred that the semiconductor device 10 further include the support substrate 600 bonded to the surface of the filling layer 500 that is opposite to the first element substrate 101 side. Thus, the rigidity of the semiconductor device 10 can be ensured.

The filling layer 500 and the support substrate 600 may be bonded by means of oxide film bonding. Accordingly, the bonding interface can be improved.

The first element substrate 101 includes a pixel portion having a photoelectric conversion element, and the second element substrate 201 processes a signal output from the pixel portion. Thus, the semiconductor device 10 can constitute a solid-state imaging device having a processing unit.

It is preferred that the second element substrate 201 be any of a memory element, a logic element, an analog element, an interface element, and an AI element. Thus, the processing unit of the solid-state imaging device can be provided with a specific function.

### 2. Semiconductor Device According to Example 2 of an Embodiment of the Present Technology

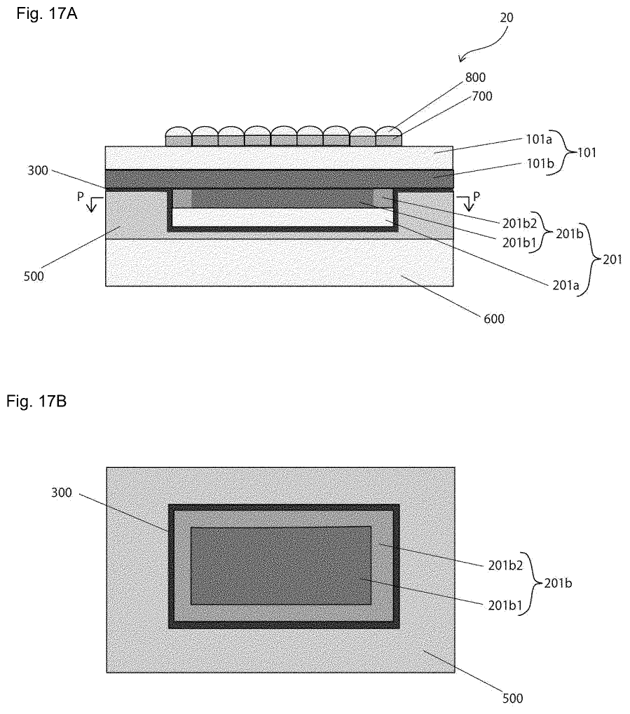

Hereinafter, a semiconductor device 20 according to Example 2 of an embodiment of the present technology will be described with reference to the drawings. FIG. 17A is a vertical cross-sectional view of the semiconductor device 20 according to Example 2 of an embodiment of the present technology. FIG. 17B is a lateral cross-sectional view of the semiconductor device 20 according to Example 2 of an embodiment of the present technology.

As shown in FIGS. 17A and 17B, the semiconductor device 20 has roughly the same configuration as the semiconductor device 10 according to Example 1 except that the thermal expansion suppression portion 201b2 is an end portion of the second wiring layer 201b (chip end).

A thermal expansion suppression portion 201b2 is provided in the shape of a frame (e.g., a rectangular shape) so as to surround a main body 201b1 of the second wiring layer 201b (see FIG. 17B).

The thermal expansion suppression portion 201b2 has a lower percentage of metal than the main body 201b1 which is a part of the second wiring layer 201b other than the thermal expansion suppression portion 201b2.

It is preferred that the percentage of metal (metal rendering rate) in the thermal expansion suppression portion 201 b2 be 10% or less. It is also preferred that the width of the thermal expansion suppression portion 201b2 in an in-plane direction be 100 μm or more.

Here, from the perspective of sufficiently suppressing distortion of the chip end, it is desirable that the CTE (linear expansion coefficient) of the wiring layer in a region 100 μm or more from the end surface of the chip (end surface of the wiring layer) is equal to or less than the CTE equivalent to that of Si (2.6 ppm/K).

If the CTE of the insulating film of the wiring layer is 0.6 ppm/K equivalent to that of TEOS, SiN, the CTE of the metal is 17.4 ppm/K equivalent to that of Cu, and the metal rendering rate is represented by x, the CTE of the entire wiring layer is CTE≈(0.6 x (1−x)+17.4 x x). Therefore, x needs to be less than 0.11 in order to obtain CTE ≤2.6 ppm/K.

Further, in a case where the difference in Young's modulus is great between the film types, the CTE estimation method varies. If the insulating film has low-k and has a CTE of 11 ppm/K and Young's modulus of 7.7 Gpa, and the metal has a CTE of 17.4 ppm/K equivalent to that of Cu and Young's modulus of 115 Gpa, the CTE of the entire wiring layer is estimated as CTE≈{11 x 7.7 x (1−x)+17.4 x 115 x x}/(7.7+115). Therefore, x needs to be less than 0.122 in order to obtain CTE ≤2.6 ppm/K. Therefore, it is preferred that the metal rendering rate be 10% or less.

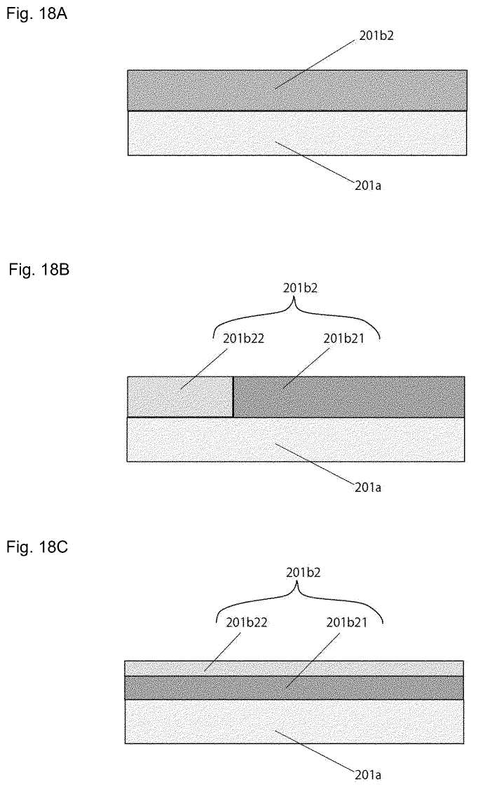

The percentage of the metal in the thermal expansion suppression portion 201b2 may be uniform overall (e.g., 10% or less) (see FIG. 18A).

The thermal expansion suppression portion 201b2 may have a plurality of parts that are arranged in the in-plane direction and have different percentages of metal. For example, the thermal expansion suppression portion 201b2 may have a first part 201b21 on the main body 201b1 side of the second wiring layer 201b, the first part 201 b21 having a relatively high percentage of metal (e.g., 20%), and a second part 201b22 on the end surface side of the second wiring layer 201b, the second part 201 b22 having a relatively low percentage of metal (e.g., 0%) (see FIG. 18B).

The thermal expansion suppression portion 201b2 may have a plurality of parts that are arranged in a lamination direction and have different percentages of metal. For example, the thermal expansion suppression portion 201b2 may have the first part 201b21 on the semiconductor substrate 201a side of the second wiring layer 201 b, the first part 201 b21 having a relatively high percentage of metal (e.g., 20%), and the second part 201b22 on the first element substrate 101 side of the second wiring layer 201b, the second part 201b22 having a relatively low percentage of metal (e.g., 0%) (see FIG. 18C).

Therefore, it is preferred that the thermal expansion suppression portion 201b2 have a width of 100 μm or more in the in-plane direction and a percentage of metal of 10% or more on average.

It is preferred that the main body 201b1 and the thermal expansion suppression portion 201b2 include any one of Cu, Al, W, Au, Co, Ta, and Ti, for example.

The thermal expansion suppression portion 201b2 may substantially function as a part of the second wiring layer 201b or as a dummy circuit, a pad portion, or the like.

### Method of Manufacturing Semiconductor Device

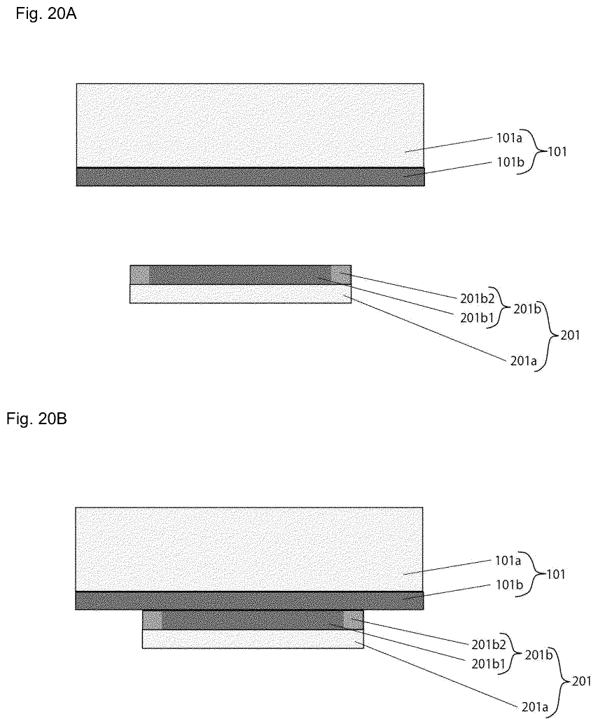

A method of manufacturing the semiconductor device 20 according to Example 2 of an embodiment of the present technology will be described hereinafter with reference to the flowchart of FIG. 119 and FIGS. 20A to 23B.

In the first step S21, the first and second element substrates 101 and 201 are prepared (see FIG. 20A). Specifically, the first element substrate 101 is generated by forming an element (e.g., pixel portion) in the first semiconductor substrate 101a and forming the first wiring layer 101b on the first semiconductor substrate 101a by means of photolithography. The second element substrate 201 is generated by forming an element (e.g., logic element) in the second semiconductor substrate 201a and forming the second wiring layer 201b on the second semiconductor substrate 201a by means of photolithography. In doing so, the second wiring layer 201b is generated in such a manner that the thermal expansion suppression portion 201b2 surrounds the main body 201b1.

In the next step S22, the first and second element substrates 101 and 201 are bonded (see FIG. 20B). Specifically, the first and second element substrates 101 and 201 are bonded by means of, for example, metal bonding, in such a manner that the first wiring layer 101b of the first element substrate 101 and the second wiring layer 201b of the second element substrate 201 face each other.

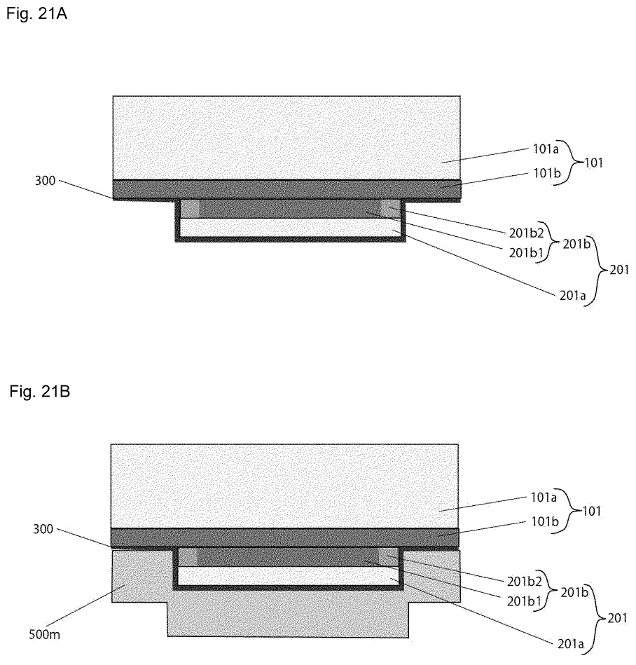

In the next step S23, the protective film 300 is formed (see FIG. 21A). Specifically, the protective film 300 (e.g., SiN film) is thinly formed so as to cover the exposed surfaces of the first and second wiring layers 101b and 201b and the second semiconductor substrate 201a.

In the next step S24, the filling film 500m is formed (see FIG. 21B). Specifically, the filling film 500m (e.g., inorganic film or organic film) serving as the filling layer 500 is formed on the entire surface. More specifically, the filling film 500m is formed thick so as to fill in the end surface side and rear surface side of the second element substrate 201.

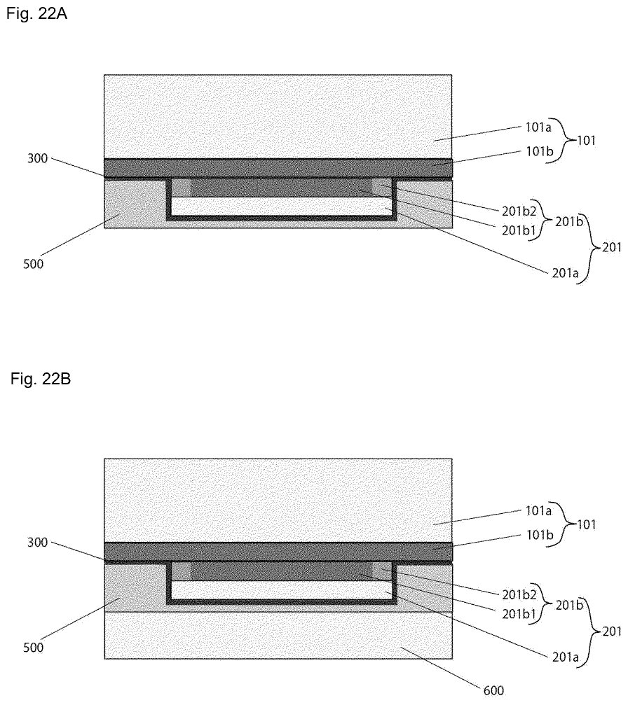

In the next step S25, the filling film 500m is made flat (see FIG. 22A). Specifically, the filling film 500m is polished using, for example, a CMP device (see FIG. 21B) until there is no unevenness. As a result, a uniformly flat filling layer 500 is generated.

In the next step S26, the support substrate 600 is bonded (see FIG. 22B). Specifically, the support substrate 600 is bonded to the rear surface of the filling layer 500 by, for example, oxide film bonding.

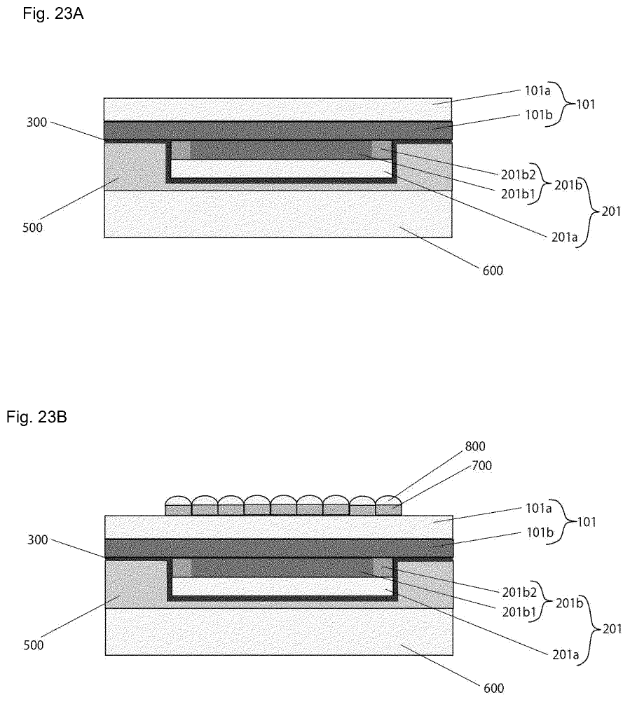

In the next step S27, the first semiconductor substrate 101a of the first element substrate 101 is made thin (see FIG. 23A). Specifically, the rear surface of the first semiconductor substrate 101a (upper surface) is polished and made thin into a desired thickness by using, for example, the CMP device.

In the final step S28, the color filter 700 and the on-chip lens 800 are formed (see FIG. 23B). Specifically, the color filter 700 and the on-chip lens 800 are sequentially formed on the rear surface side of the first semiconductor substrate 101a.

### Advantageous Effects of Semiconductor Device

According to the semiconductor device 20, the same advantageous effects as those of the semiconductor device 10 according to Example 1 can be achieved, and since the thermal expansion suppression portion 201b2 is the end portion of the second wiring layer 201b, it is not necessary to provide the thermal expansion suppression portion separately, simplifying the manufacturing process.

### 3. Semiconductor Device According to Example 3 of an Embodiment of the Present Technology

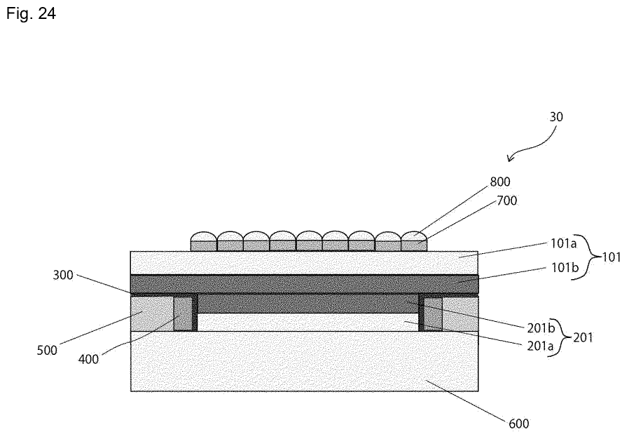

Hereinafter, a semiconductor device 30 according to Example 3 of an embodiment of the present technology will be described with reference to the drawings. FIG. 24 is a vertical cross-sectional view of the semiconductor device 30 according to Example 3 of an embodiment of the present technology.

As shown in FIG. 24, the semiconductor device 30 has roughly the same configuration as the semiconductor device 10 according to Example 1, except that the filling layer 500 fills in only the end surface side of the second element substrate 201 in which the thermal expansion suppression portion 400 is provided on the end surface thereof via the protective film 300.

In the semiconductor device 30, a rear surface of the second semiconductor substrate 201a (lower surface) is flush with the rear surface of the filling layer 500 (lower surface).

In the semiconductor device 30, the support substrate 600 and the second semiconductor substrate 201a are bonded to each other by, for example, semiconductor direct bonding.

### Method of Manufacturing Semiconductor Device

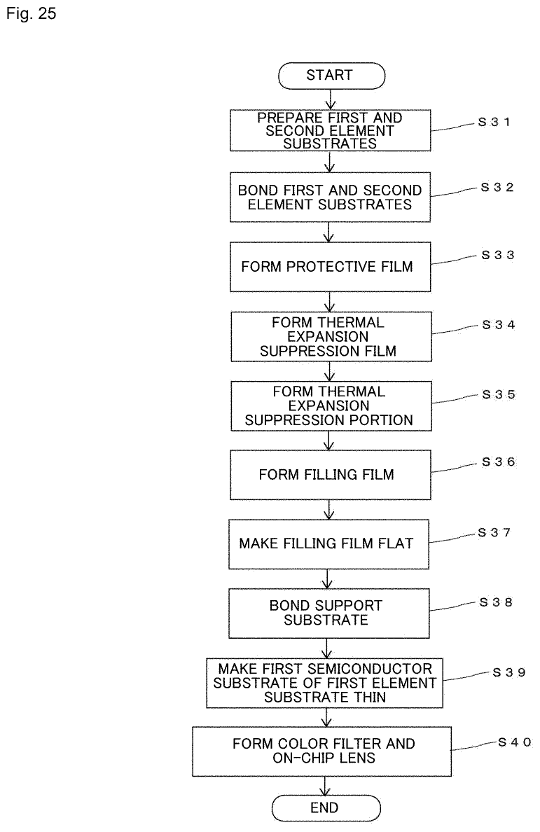

A method of manufacturing the semiconductor device 30 according to Example 3 of an embodiment of the present technology will be described hereinafter with reference to the flowchart of FIG. 25, FIGS. 12A to 14B, and FIGS. 26A to 27B.

In the first step S31, the first and second element substrates 101 and 201 are prepared (see FIG. 12A). Specifically, the first element substrate 101 is generated by forming an element (e.g., pixel portion) in the first semiconductor substrate 101a and forming the first wiring layer 101b on the first semiconductor substrate 101a by means of photolithography. The second element substrate 201 is generated by forming an element (e.g., logic element) in the second semiconductor substrate 201a and forming the second wiring layer 201b on the second semiconductor substrate 201a by means of photolithography.

In the next step S32, the first and second element substrates 101 and 201 are bonded (see FIG. 12B). Specifically, the first and second element substrates 101 and 201 are bonded by means of, for example, metal bonding, in such a manner that the first wiring layer 101b of the first element substrate 101 and the second wiring layer 201b of the second element substrate 201 face each other.

In the next step S33, the protective film 300 is formed (see FIG. 13A). Specifically, the protective film 300 (e.g., SiN film) is thinly formed so as to cover the exposed surfaces of the first and second wiring layers 101b and 201b and the second semiconductor substrate 201a.

In the next step S34, the thermal expansion suppression film 400m is formed (see FIG. 13B). Specifically, the thermal expansion suppression film 400m serving as the thermal expansion suppression portion 400 is formed thick so as to cover the protective film 300.

In the next step S35, the thermal expansion suppression portion 400 is formed (see FIG. 14A). Specifically, first, the thermal expansion suppression film 400m is polished and made flat by using, for example, a CMP (Chemical Mechanical Polisher) device. In this case, the protective film 300 functions as a polishing stop layer. Next, the thermal expansion suppression film 400m is etched to leave only the thermal expansion suppression portion 400. In this case, the protective film 300 functions as an etching stop layer.

In the next step S36, the filling film 500m is formed (see FIG. 14B). Specifically, the filling film 500m (e.g., inorganic film or organic film) serving as the filling layer 500 is formed on the entire surface. More specifically, the filling film 500m is formed so as to fill in the end surface side and rear surface side of the second element substrate 201 where the thermal expansion suppression portion 400 is provided on the end surface of the second element substrate 201 via the protective film 300.

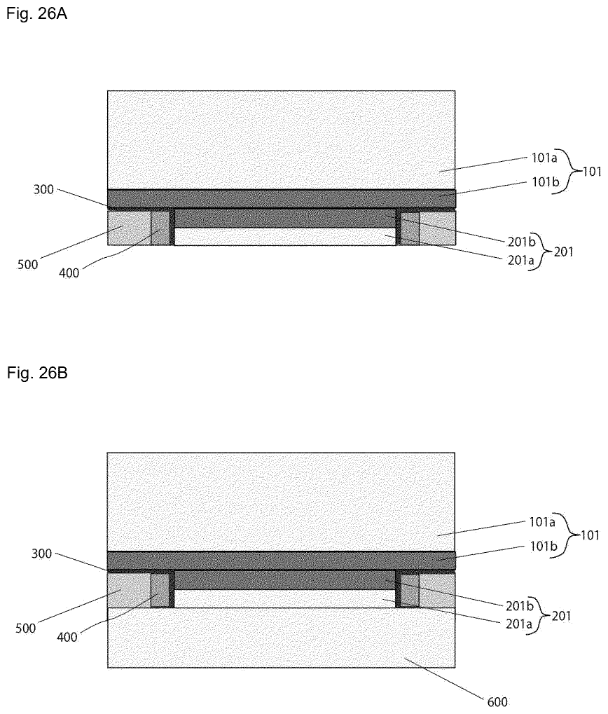

In the next step S37, the filling film 500m is made flat (see FIG. 26A). Specifically, by using, for example, the CMP device, the filling film 500m (see FIG. 14B) and the protective film 300 provided on the rear surface of the second semiconductor substrate 201a are polished until the second semiconductor substrate 201a is exposed. As a result, the filling layer 500 for filling in the periphery of the thermal expansion suppression portion 400 is generated.

In the next step S38, the support substrate 600 is bonded (see FIG. 26B). Specifically, the second semiconductor substrate 201a and the support substrate 600 are bonded to each other by, for example, semiconductor direct bonding.

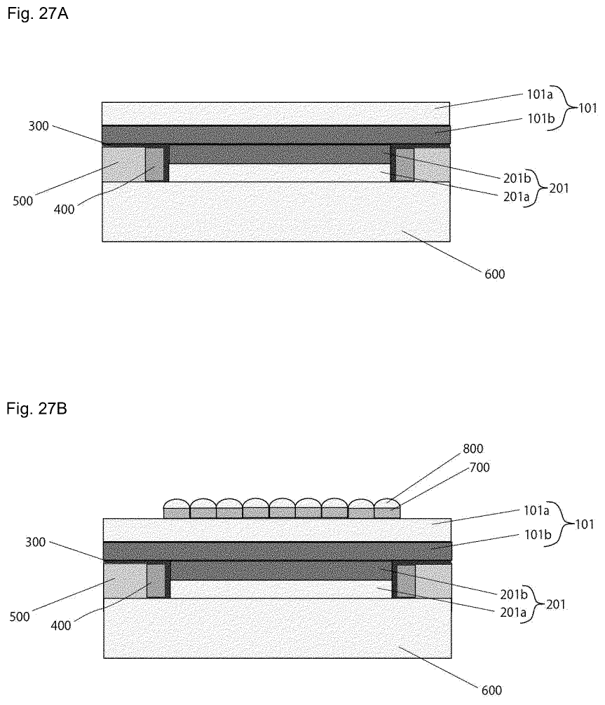

In the next step S39, the first semiconductor substrate 101a of the first element substrate 101 is made thin (see FIG. 27A). Specifically, the rear surface of the first semiconductor substrate 101a (upper surface) is polished and made thin into a desired thickness by using, for example, the CMP device.

In the final step S40, the color filter 700 and the on-chip lens 800 are formed (see FIG. 27B). Specifically, the color filter 700 and the on-chip lens 800 are sequentially formed on the rear surface side of the first semiconductor substrate 101a.

### Advantageous Effects of Semiconductor Device

According to the semiconductor device 30, the same advantageous effects as those of the semiconductor device 10 according to Example 1 can be achieved, and since the filling layer 500 is not provided on the rear surface side of the second semiconductor substrate 201a, heat dissipation from the rear surface to the support substrate 600 can be improved.

### 4. Semiconductor Device According to Example 4 of an Embodiment of the Present Technology

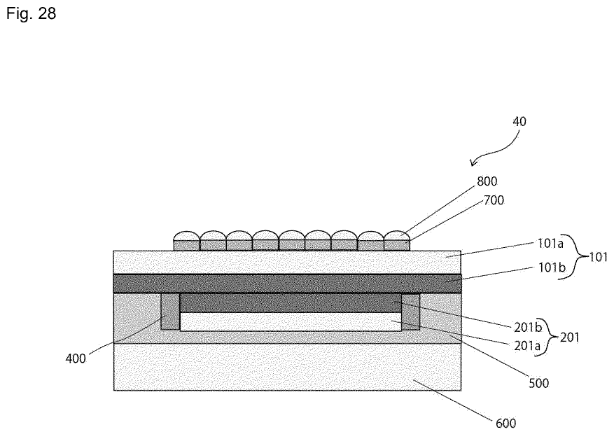

Hereinafter, a semiconductor device 40 according to Example 4 of an embodiment of the present technology will be described with reference to the drawings. FIG. 28 is a vertical cross-sectional view of the semiconductor device 40 according to Example 4 of an embodiment of the present technology.

As shown in FIG. 28, the semiconductor device 40 has the same configuration as the semiconductor device 10 according to Example 1, except that the protective film 300 is not provided.

According to the semiconductor device 40, the same advantageous effects as those of the semiconductor device 10 according to Example 1 can be achieved, except that the advantageous effects by the protective film 300 cannot be obtained, whereby the configuration can be made simple and the manufacturing process can be simplified.

### 5. Semiconductor Device According to Example 5 of an Embodiment of the Present Technology

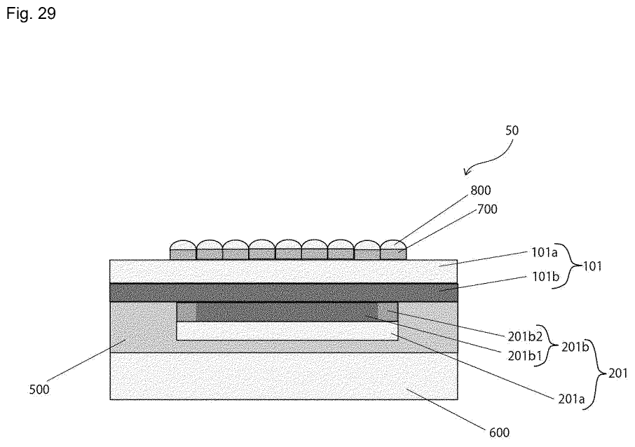

Hereinafter, a semiconductor device 50 according to Example 5 of an embodiment of the present technology will be described with reference to the drawings. FIG. 29 is a vertical cross-sectional view of the semiconductor device 50 according to Example 5 of an embodiment of the present technology.

As shown in FIG. 29, the semiconductor device 50 has the same configuration as the semiconductor device 20 according to Example 2, except that the protective film 300 is not provided.

According to the semiconductor device 50, the same advantageous effects as those of the semiconductor device 20 according to Example 2 can be achieved, except that the advantageous effects by the protective film 300 cannot be obtained, whereby the configuration can be made simple and the manufacturing process can be simplified.

### 6. Semiconductor Device According to Example 6 of an Embodiment of the Present Technology

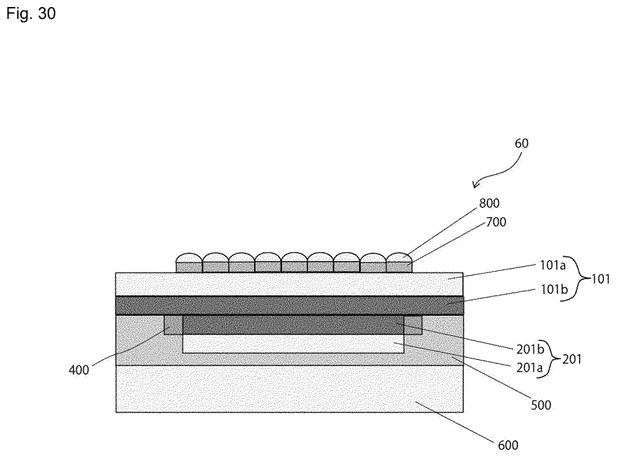

Hereinafter, a semiconductor device 60 according to Example 6 of an embodiment of the present technology will be described with reference to the drawings. FIG. 30 is a vertical cross-sectional view of the semiconductor device 60 according to Example 6 of an embodiment of the present technology.

As shown in FIG. 30, the semiconductor device 60 has the same configuration as the semiconductor device 10 according to Example 1, except that the protective film 300 is not provided and that the thermal expansion suppression portion 400 is provided only on the end surface of the second wiring layer 201b (partial end surface of the end portion of the second element substrate 201 on the first element substrate 101 side).

According to the semiconductor device 60, the same advantageous effects as those of the semiconductor device 10 according to Example 1 can be achieved, except that the advantageous effects by the protective film 300 cannot be obtained, whereby the configuration can be made simple and the manufacturing process can be simplified.

### 7. Semiconductor Device According to Example 7 of an Embodiment of the Present Technology

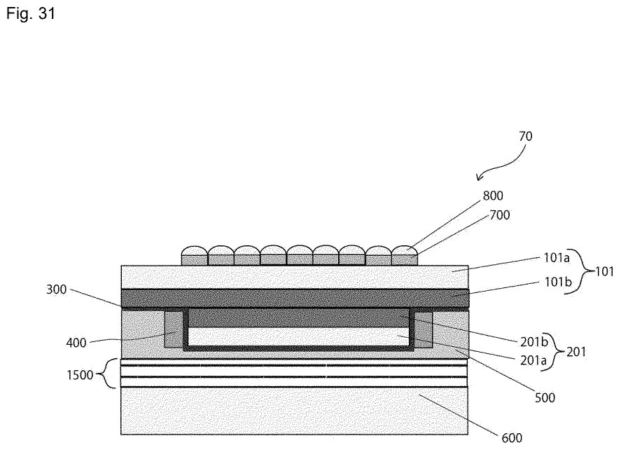

Hereinafter, a semiconductor device 70 according to Example 7 of an embodiment of the present technology will be described with reference to the drawings. FIG. 31 is a vertical cross-sectional view of the semiconductor device 70 according to Example 7 of an embodiment of the present technology.

The semiconductor device 70 has, as shown in FIG. 31, the same configuration as the semiconductor device 10 according to Example 1, except that a multilayer film 1500 is provided as a heat dissipation member bonded to a surface of the filling layer 500 that is opposite to the first element substrate 101 side.

As an example, the multilayer film 1500 is arranged between the filling layer 500 and the support substrate 600.

Although the material of a plurality of films of the multilayer film 1500 is not particularly limited, it is preferred that the material be a material with high heat dissipation. Specifically, it is preferred that the multilayer film 1500 include any of SiC, AIN, SiN, Cu, Al, and C.

The multilayer film 1500 may include a plurality of films made of the same material or a plurality of films made of different materials. Note that the multilayer film 1500 may be replaced with a single-layer film (e.g., a film with high heat dissipation). It is preferred that the single-layer film also include any of SiC, AIN, SiN, Cu, Al, and C.

### 8. Semiconductor Device According to Example 8 of an Embodiment of the Present Technology

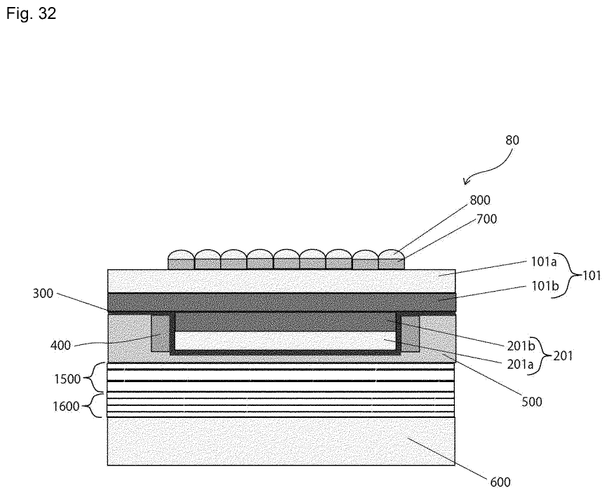

Hereinafter, a semiconductor device 80 according to Example 8 of an embodiment of the present technology will be described with reference to the drawings. FIG. 32 is a vertical cross-sectional view of the semiconductor device 80 according to Example 8 of an embodiment of the present technology.

As shown in FIG. 32, the semiconductor device 80 has the same configuration as the semiconductor device 10 according to Example 1, except that multilayer films 1500, 1600 in which a plurality of films are laminated are laminated with each other between the filling layer 500 and the support substrate 600.

Although the material of the plurality of films of each of the multilayer films is not particularly limited, it is preferred that the material be a material with high heat dissipation. Specifically, it is preferred that each of the multilayer films include any of SiC, AIN, SiN, Cu, Al, and C.

Each of the multilayer films may include a plurality of films made of the same material or a plurality of films made of different materials. Note that at least either one of the multilayer films 1500, 1600 may be replaced with a single-layer film (e.g., a film with high heat dissipation). It is preferred that the single-layer film also include any of SiC, AIN, SiN, Cu, Al, and C. Further, another multilayer film or single-layer film may be laminated on the multilayer films 1500, 1600.

### 9. Semiconductor device according to Example 9 of an embodiment of the present Technology

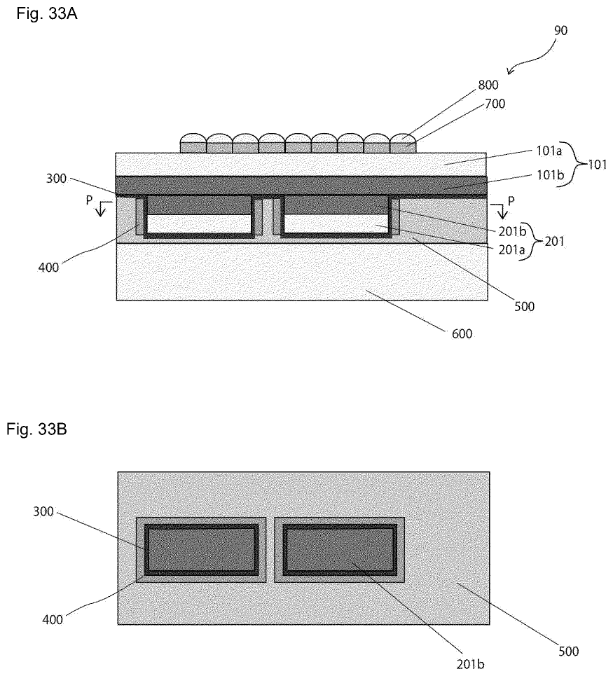

Hereinafter, a semiconductor device 90 according to Example 9 of an embodiment of the present technology will be described with reference to the drawings. FIG. 33A is a vertical cross-sectional view of the semiconductor device 90 according to Example 9 of an embodiment of the present technology. FIG. 33B is a lateral cross-sectional view of the semiconductor device 90 according to Example 9 of an embodiment of the present technology.

As shown in FIGS. 33A and 33B, the semiconductor device 90 has roughly the same configuration as the semiconductor device 10 according to Example 1, except that a plurality (e.g., two) of the second element substrates 201 are provided.

It is preferred that the plurality (e.g., two) of second element substrates 201 be provided with different elements. Some of the plurality of element substrates 201 may include dummy elements. The size and/or thickness of the plurality of second element substrates 201 may be same or different.

According to the semiconductor device 90, the same advantageous effects as those of the semiconductor device 10 according to Example 1 can be achieved, and since the plurality of second element substrates 201 are provided, a processing unit of the semiconductor device 90 can have a plurality of functions, and accordingly a device with high added value can be provided.

### 10. Semiconductor Device 10 According to Example 10 of an Embodiment of the Present Technology

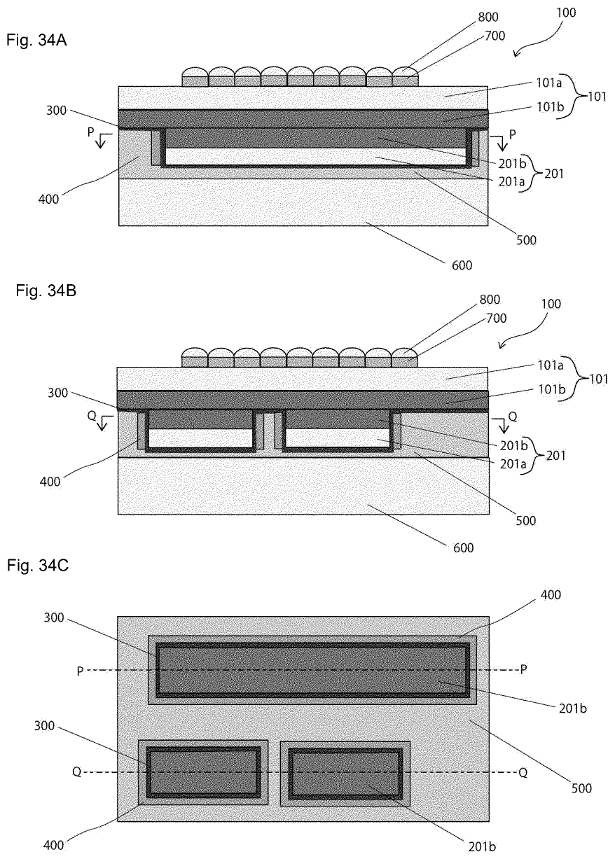

A semiconductor device 100 according to example 10 of an embodiment of the present technology will be described hereinafter with reference to the drawings. FIG. 34A is a vertical cross-sectional view (1) of the semiconductor device 100 according to Example 10 of an embodiment of the present technology. FIG. 34B is a vertical cross-sectional view (2) of the semiconductor device 100 according to Example 10 of an embodiment of the present technology. FIG. 34C is a lateral cross-sectional view of the semiconductor device 100 according to Example 10 of an embodiment of the present technology. FIG. 34A is a cross-sectional view taken along line P-P of FIG. 34C. FIG. 34B is a cross-sectional view taken along line Q-Q of FIG. 34C.

The semiconductor device 100 has, as shown in FIGS. 34A to 34C, roughly the same configuration as the semiconductor device 10 according to Example 1, except that at least three (e.g., three) second element substrates 201 are provided in the same layer.

It is preferred that at least three (e.g., three) second element substrates 201 be provided with different elements. Some of the plurality of element substrates 201 may include dummy elements. The size and/or thickness of the plurality of second element substrates 201 may be same or different.

In the semiconductor device 100, at least three (e.g., three) second element substrates 201 are arranged two-dimensionally but may be arranged one-dimensionally.

According to the semiconductor device 100, the same advantageous effects as those of the semiconductor device 10 according to Example 1 can be achieved, and since at least three second element substrates 201 are provided, a processing unit of the semiconductor device 100 can have at least three functions, and accordingly a device with higher added value can be provided.

### 11. Semiconductor Device According to Example 11 of an Embodiment of the Present Technology

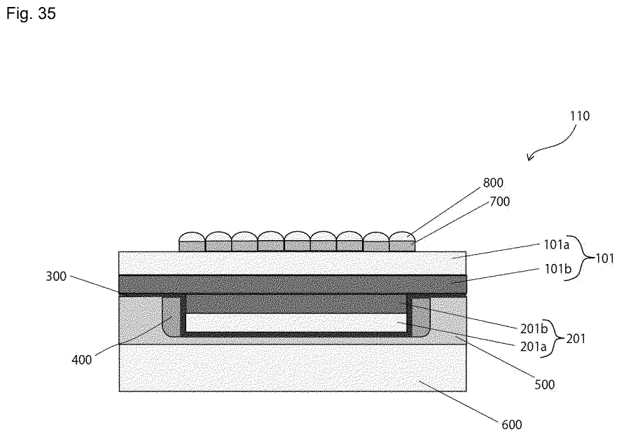

Hereinafter, a semiconductor device 110 according to Example 11 of an embodiment of the present technology will be described with reference to the drawings. FIG. 35 is a vertical cross-sectional view of the semiconductor device 110 according to Example 11 of an embodiment of the present technology.

As shown in FIG. 35, the semiconductor device 110 has the same configuration as the semiconductor device 10 according to Example 1, except that the corners of the thermal expansion suppression portion 400 are rounded. If the corners of the thermal expansion suppression portion 400 are sharp, stress tends to concentrate at the corners. According to the semiconductor device 110, by making the corners of the thermal expansion suppression portion 400 round, a region with a steep angle in the filling layer 500 can be reduced, which is advantageous in terms of reliability (less prone to breakage).

### 12. Semiconductor Device According to Example 12 of an Embodiment of the Present Technology

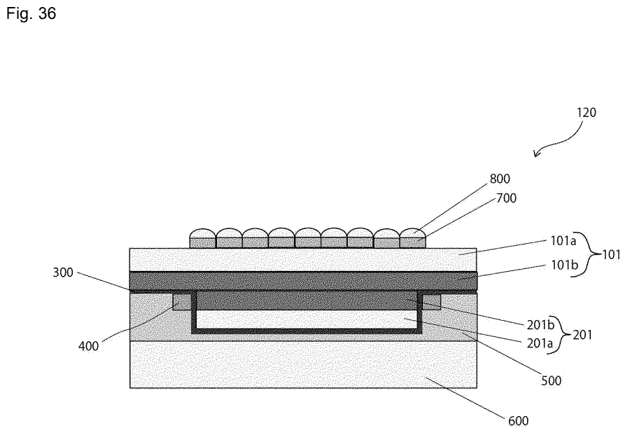

Hereinafter, a semiconductor device 120 according to Example 12 of an embodiment of the present technology will be described with reference to the drawings. FIG. 36 is a vertical cross-sectional view of the semiconductor device 120 according to Example 12 of an embodiment of the present technology.

The semiconductor device 120 has, as shown in FIG. 36, the same configuration as the semiconductor device 10 according to Example 1, except that the thermal expansion suppression portion 400 is provided only on the end surface of the second wiring layer 201b via the protective film 300.

### 13. Semiconductor Device According to Example 13 of an Embodiment of the Present Technology

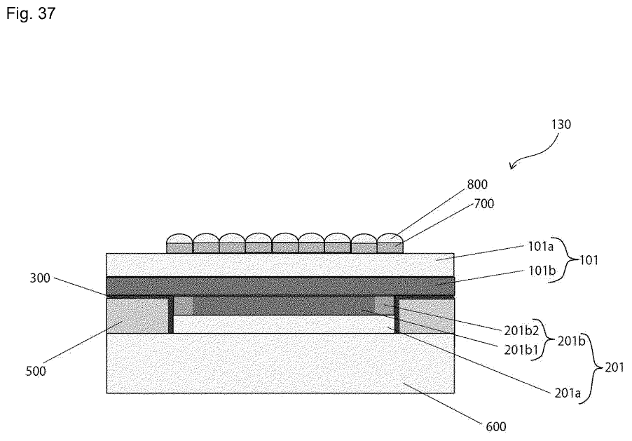

Hereinafter, a semiconductor device 130 according to Example 13 of an embodiment of the present technology will be described with reference to the drawings. FIG. 37 is a vertical cross-sectional view of the semiconductor device 130 according to Example 13 of an embodiment of the present technology.

As shown in FIG. 37, the semiconductor device 130 has roughly the same configuration as the semiconductor device 20 according to Example 2, except that the filling layer 500 is provided only on the end surface side of the second element substrate 201.

In the semiconductor device 130, as an example, the support substrate 600 and the second semiconductor substrate 201a are bonded to each other by semiconductor direct bonding.

According to the semiconductor device 40, the same advantageous effects as those of the semiconductor device 20 according to Example 2 can be achieved, and since the filling layer 500 is not provided on the rear surface side of the second semiconductor substrate 201a, heat dissipation from the rear surface to the support substrate 600 can be improved.

### 14. Semiconductor Device According to Example 14 of an Embodiment of the Present Technology

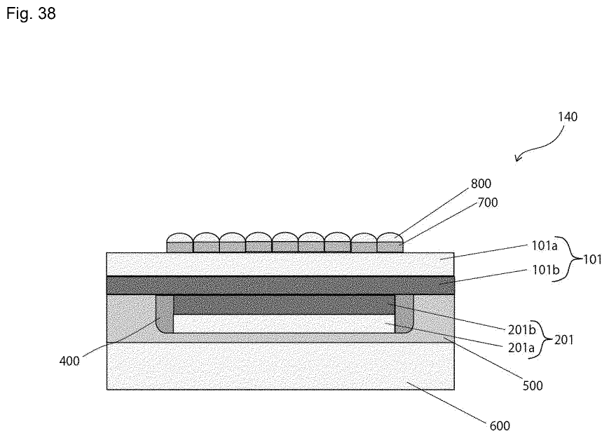

Hereinafter, a semiconductor device 140 according to Example 14 of an embodiment of the present technology will be described with reference to the drawings. FIG. 38 is a vertical cross-sectional view of the semiconductor device 140 according to Example 14 of an embodiment of the present technology.

As shown in FIG. 38, the semiconductor device 140 has the same configuration of the semiconductor device 40 according to Example 4 (see FIG. 28), except that the corners of the thermal expansion suppression portion 400 are rounded. According to the semiconductor device 140, the same advantageous effects as those of the semiconductor device 110 according to Example 11 (see FIG. 35) can be achieved.

### 15. Semiconductor Device According to Example 15 of an Embodiment of the Present Technology

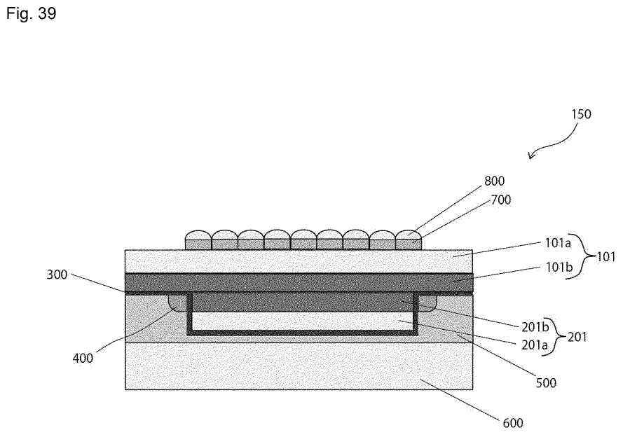

Hereinafter, a semiconductor device 150 according to Example 15 of an embodiment of the present technology will be described with reference to the drawings. FIG. 39 is a vertical cross-sectional view of the semiconductor device 150 according to Example 15 of an embodiment of the present technology.

As shown in FIG. 39, the semiconductor device 150 has the same configuration of the semiconductor device 120 according to Example 12 (see FIG. 36), except that the corners of the thermal expansion suppression portion 400 are rounded. According to the semiconductor device 150, the same advantageous effects as those of the semiconductor device 110 according to Example 11 (see FIG. 35) can be achieved.

### 16. Semiconductor Device According to Example 16 of an Embodiment of the Present Technology

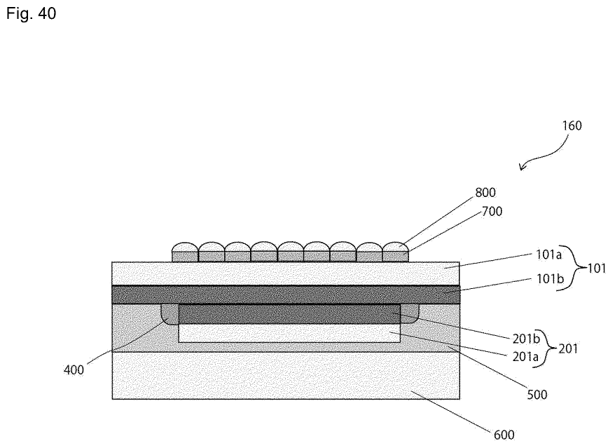

Hereinafter, a semiconductor device 160 according to Example 16 of an embodiment of the present technology will be described with reference to the drawings. FIG. 40 is a vertical cross-sectional view of the semiconductor device 160 according to Example 16 of an embodiment of the present technology.

As shown in FIG. 40, the semiconductor device 160 has the same configuration of the semiconductor device 60 according to Example 6 (see FIG. 30), except that the corners of the thermal expansion suppression portion 400 are rounded. According to the semiconductor device 160, the same advantageous effects as those of the semiconductor device 110 according to Example 11 (see FIG. 35) can be achieved.

### 17. Semiconductor Device According to Example 17 of an Embodiment of the Present Technology

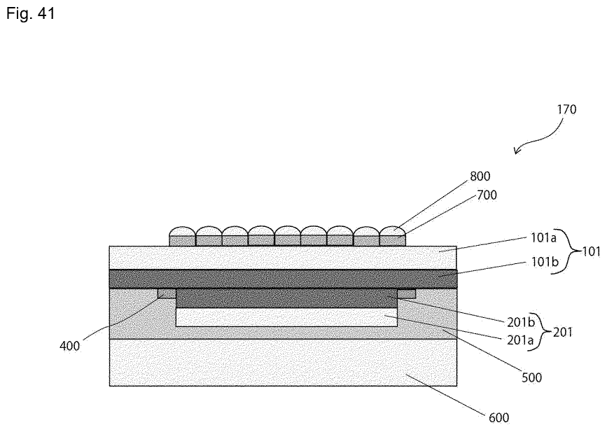

Hereinafter, a semiconductor device 170 according to Example 17 of an embodiment of the present technology will be described with reference to the drawings. FIG. 41 is a vertical cross-sectional view of the semiconductor device 170 according to Example 17 of an embodiment of the present technology.

As shown in FIG. 41, the semiconductor device 170 has the same configuration as the semiconductor device 60 according to Example 6 (see FIG. 30), except that the thermal expansion suppression portion 400 is provided on an end surface of a part of the end portion of the second wiring layer 201b on the first element substrate 101 side.

### 18. Semiconductor Device According to Example 18 of an Embodiment of the Present Technology

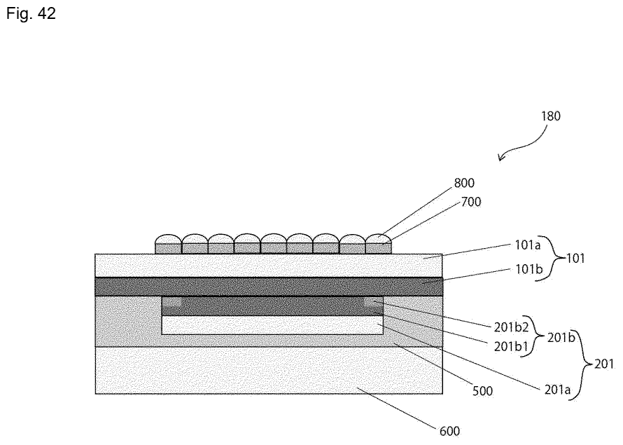

Hereinafter, a semiconductor device 180 according to Example 18 of an embodiment of the present technology will be described with reference to the drawings. FIG. 42 is a vertical cross-sectional view of the semiconductor device 180 according to Example 18 of an embodiment of the present technology.

As shown in FIG. 42, the semiconductor device 180 has the same configuration as the semiconductor device 50 according to Example 5 (see FIG. 29), except that the thermal expansion suppression portion 201b2 is the part of the end portion of the second wiring layer 201b on the first element substrate 101 side.

### 19. Semiconductor Device According to Example 19 of an Embodiment of the Present Technology

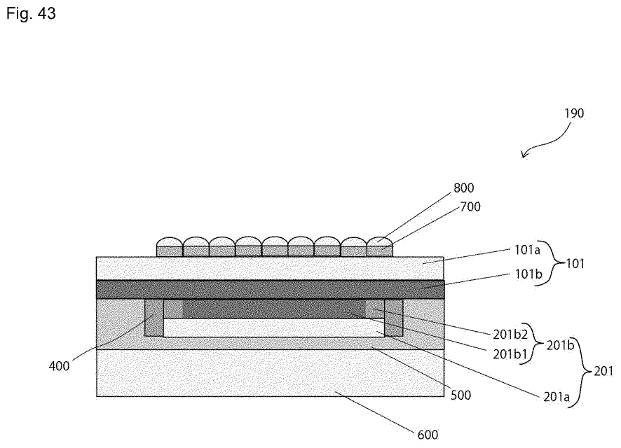

Hereinafter, a semiconductor device 190 according to Example 19 of an embodiment of the present technology will be described with reference to the drawings. FIG. 43 is a vertical cross-sectional view of the semiconductor device 190 according to Example 19 of an embodiment of the present technology.

As shown in FIG. 43, the semiconductor device 190 has the same configuration as the semiconductor device 50 according to Example 5 (see FIG. 29), except that the end surface of the second element substrate 201 that has the thermal expansion suppression portion 201b2 is further provided with the thermal expansion suppression portion 400.

### 20. Semiconductor Device According to Example 20 of an Embodiment of the Present Technology

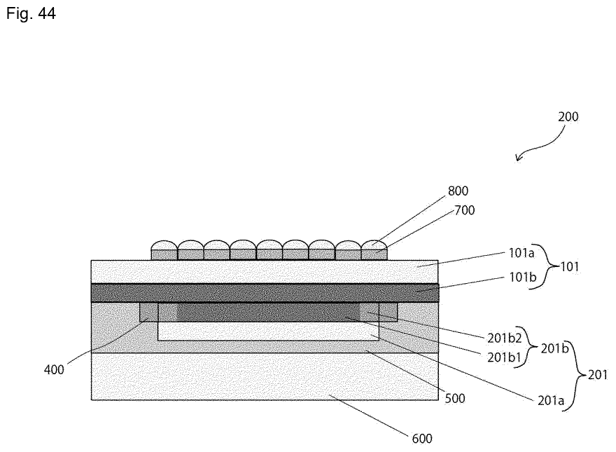

Hereinafter, a semiconductor device 200 according to Example 20 of an embodiment of the present technology will be described with reference to the drawings. FIG. 44 is a vertical cross-sectional view of the semiconductor device 200 according to Example 20 of an embodiment of the present technology.

As shown in FIG. 44, the semiconductor device 200 has the same configuration as the semiconductor device 50 according to Example 5 (see FIG. 29), except that an end surface of the thermal expansion suppression portion 201b2 of the second element substrate 201 having the thermal expansion suppression portion 201b2 is further provided with the thermal expansion suppression portion 400.

### 21. Semiconductor Device According to Example 21 of an Embodiment of the Present Technology

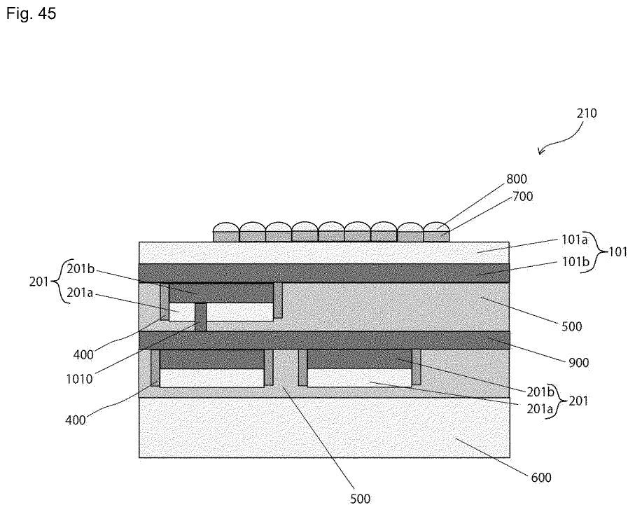

Hereinafter, a semiconductor device 210 according to Example 21 of an embodiment of the present technology will be described with reference to the drawings. FIG. 45 is a vertical cross-sectional view of the semiconductor device 210 according to Example 21 of an embodiment of the present technology.

As shown in FIG. 45, the semiconductor device 210 has roughly the same configuration as the semiconductor device 10 according to Example 1, except that a plurality of the second element substrates 201 are provided.

In the semiconductor device 210, the plurality of second element substrates 201 include a layer (also referred to as “middle layer,” hereinafter) composed of at least one (e.g., one) second element substrate 201 bonded to the first element substrate 101 (also referred to as “upper layer,” hereinafter), and a layer (also referred to as “lower layer,” hereinafter) composed of at least two second element substrates 201 arranged in the in-plane direction on the opposite side of the second element substrate 201 from the first element substrate 101. That is, the semiconductor device 210 has a three-layer structure in which three of a layer composed of at least one element substrate are laminated.

A wiring layer 900 is arranged between the filling layer 500 provided on the rear surface side of the middle layer and the lower layer. The middle layer is provided with a through electrode 1010 that penetrates the second semiconductor substrate 201a of the middle layer and the filling layer 500 on the rear surface side of the second semiconductor substrate 201a and has one end connected electrically to the second wiring layer 201b of the middle layer and the other end connected electrically to the wiring layer 900. The second wiring layer 201b of the lower layer is directly bonded to the wiring layer 900 by, for example, metal wiring.

According to the semiconductor device 210, the same advantageous effects as those of the semiconductor device 10 according to Example 1 can be achieved, and since the plurality of second element substrates 201 are arranged in the in-plane direction and the lamination direction, many functions can be incorporated in the processing unit in a reduced space with respect to the in-plane direction.

### 22. Semiconductor Device According to Example 22 of an Embodiment the Present Technology

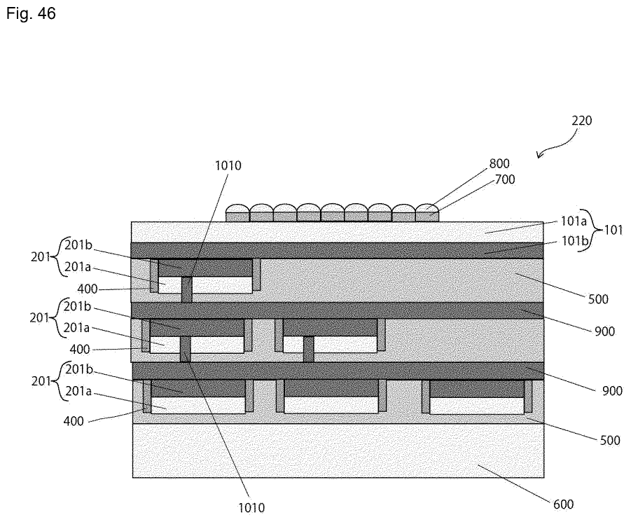

Hereinafter, a semiconductor device 220 according to Example 22 of an embodiment of the present technology will be described with reference to the drawings. FIG. 46 is a vertical cross-sectional view of the semiconductor device 220 according to Example 22 of an embodiment of the present technology.

As shown in FIG. 46, the semiconductor device 220 has roughly the same configuration as the semiconductor device 210 according to Example 21 (see FIG. 45), except that the semiconductor device 220 has a four-layer structure in which another layer composed of at least two (e.g., three) second element substrates 201 arranged in the in-plane direction is laminated below.

According to the semiconductor device 220, the same advantageous effects as those of the semiconductor device 10 according to Example 1 can be achieved, and since the plurality of second element substrates 201 are arranged in the in-plane direction and the lamination direction, many functions can be incorporated in the processing unit in a reduced space with respect to the in-plane direction.

### 23. Semiconductor Device According to Example 23 of an Embodiment of the Present Technology

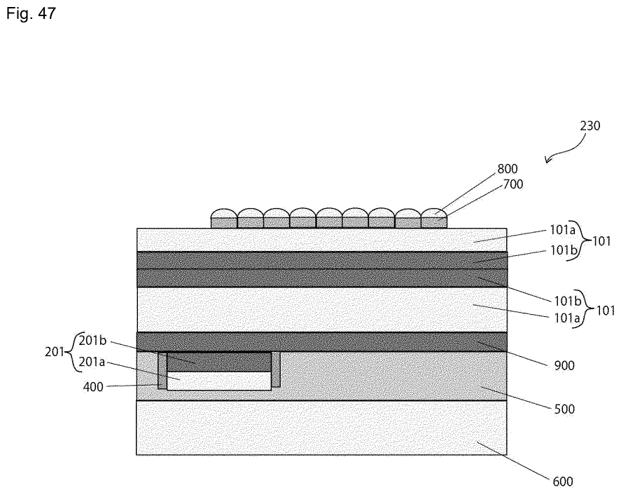

Hereinafter, a semiconductor device 230 according to Example 23 of an embodiment of the present technology will be described with reference to the drawings. FIG. 47 is a vertical cross-sectional view of the semiconductor device 230 according to Example 23 of an embodiment of the present technology.

As shown in FIG. 47, the semiconductor device 230 has the same configuration as the semiconductor device 10 according to Example 1, except that the semiconductor device 230 has a first element substrate 101 (middle layer) that is laminated with the first element substrate 101 (upper layer) by WoW and laminated with a layer (lower layer) composed of at least one second element substrate 201 by CoW. That is, the semiconductor device 230 has a three-layer structure in which three of a layer composed of at least one element substrate are laminated.

The first element substrate 101 serving as the middle layer may include any of, for example, a logic element, a memory element, an analog element, an interface element, and an AI element.

In the semiconductor device 230, the first wiring layers 101b of the upper layer and middle layer are directly bonded to each other by, for example, metal bonding, and the wiring layer 900 provided in the rear surface of the first semiconductor substrate 101a of the middle layer is bonded directly to the second wiring layer 201b of the lower layer by, for example, metal bonding.

According to the semiconductor device 230, the same advantageous effects as those of the semiconductor device 10 according to Example 1 can be achieved, and since the plurality (e.g., two) of first element substrates 101 are laminated, many functions can be incorporated in the processing unit in a reduced space with respect to the in-plane direction.

### 24. Semiconductor Device According to Example 24 of an Embodiment of the Present Technology

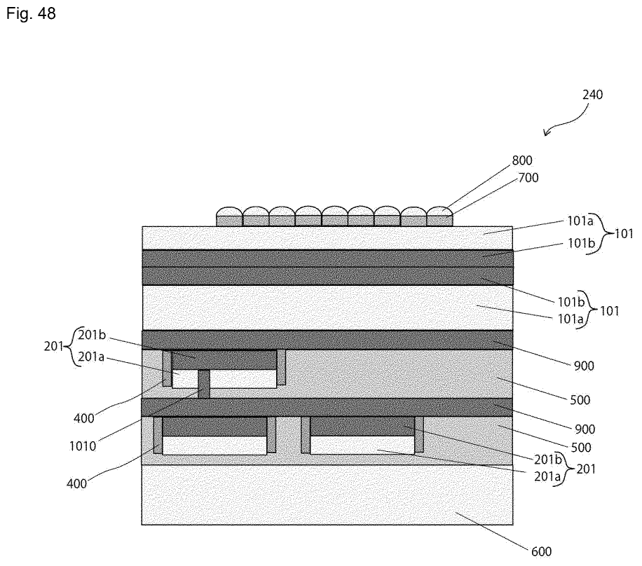

Hereinafter, a semiconductor device 240 according to Example 24 of an embodiment of the present technology will be described with reference to the drawings. FIG. 48 is a vertical cross-sectional view of the semiconductor device 240 according to Example 24 of an embodiment of the present technology.

As shown in FIG. 48, the semiconductor device 240 has the same configuration as the semiconductor device 210 according to Example 21 (see FIG. 45), except that the semiconductor device 240 has a first element substrate 101 (second layer: middle layer) that is laminated with the first element substrate 101 (first layer: upper layer) by WoW and laminated with a layer (third layer: lower layer) composed of at least one second element substrate 201 by CoW. That is, the semiconductor device 240 has a four-layer structure in which four of a layer composed of at least one element substrate are laminated.

The first element substrate 101 serving as the middle layer may include any of, for example, a logic element, a memory element, an analog element, an interface element, and an AI element.

In the semiconductor device 240, the first wiring layers 101b of the upper layer (first layer) and middle layer (second layer) are bonded directly to each other by, for example, metal bonding, and the wiring layer 900 provided in the rear surface of the first semiconductor substrate 101a of the middle layer (second layer) is bonded directly to the second wiring layer 201b of the lower layer (third layer) by, for example, metal bonding.

According to the semiconductor device 240, since the plurality (e.g., two) of first element substrates 101 are laminated and a layer composed of at least one second element substrate 201 is laminated, many functions can be incorporated in the processing unit in a reduced space with respect to the in plane direction.

### 25. Semiconductor Device According to Example 25 of an Embodiment of the Present Technology

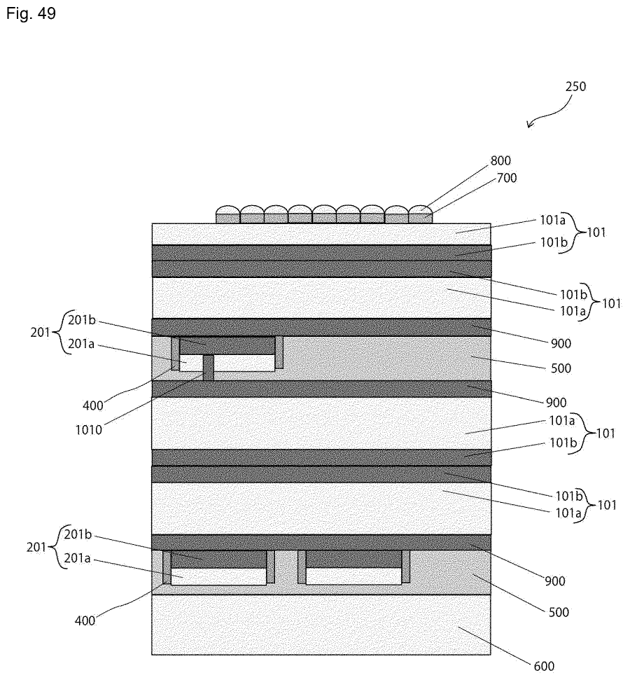

Hereinafter, a semiconductor device 250 according to Example 25 of an embodiment of the present technology will be described with reference to the drawings. FIG. 49 is a vertical cross-sectional view of the semiconductor device 250 according to Example 25 of an embodiment of the present technology.

The semiconductor device 250 has the same configuration as the semiconductor device 240 according to Example 24 (see FIG. 48), except that at least one (e.g., two) first element substrate 101 (e.g., fourth layer, fifth layer) is laminated between two layers that are laminated and composed of at least one second element substrate 201.

The first element substrate 101 serving as the middle layer may include any of, for example, a logic element, a memory element, an analog element, an interface element, and an AI element.

In the semiconductor device 250, the wiring layer 900 is arranged between the layer (third layer) composed of at least one second element substrate 201 and the first element substrate 101 (fourth layer), and the wiring layer 900 and the second wiring layer 201b of the third layer are electrically connected via the through electrode 1010. The first wiring layers 101b of the fourth layer and fifth layer (first element substrate 101) are bonded directly to each other by, for example, metal bonding. The wiring layer 900 is arranged between the fifth layer and a layer (sixth layer) composed of at least one (e.g., two) second element substrates 201, and the wiring layer 900 and the second wiring layer 201b of the sixth layer are bonded directly to each other by, for example, metal bonding.

According to the semiconductor device 250, since the plurality (e.g., four) of first element substrates 101 are laminated and, for example, two of the layer composed of at least one second element substrate 201 are laminated, many functions can be incorporated in the processing unit in a reduced space with respect to the in-plane direction.

### 26. Modifications of the Present Technology

The configuration of the semiconductor device according to each example of an embodiment described above can be changed as appropriate.

For example, the configurations of the semiconductor devices of the respective examples described above may be combined with each other within a technically consistent range.

### 27. Example of Use of an Electronic Device Provided With the Semiconductor Device According to the Present Technology

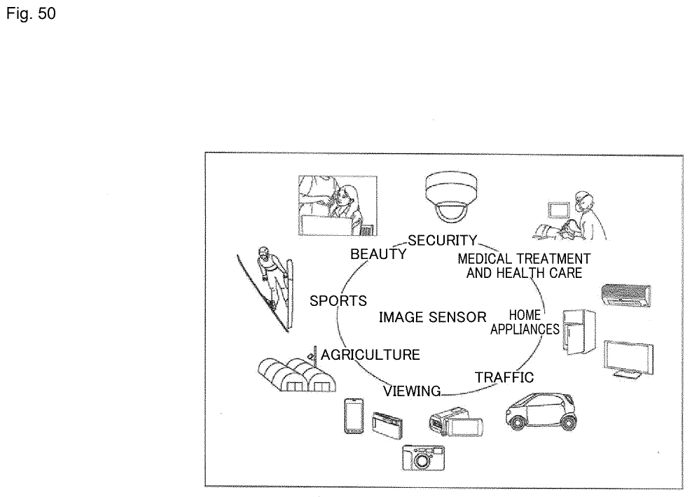

FIG. 50 is a diagram showing an example of use of an electronic device having the semiconductor device according to each example of an embodiment of the present technology and including a solid-state imaging device (image sensor).

This electronic device can be used in various cases for sensing light such as visible light, infrared light, ultraviolet light, and X-ray, as will be described below. That is, as shown in FIG. 50, the electronic device can be used in devices which are applied to, for example, a field of viewing where images are captured for viewing, a field of traffic, a field of home appliances, a field of medical treatment and health care, a field of security, a field of beauty, a field of sports, and a field of agriculture.

Specifically, in the field of viewing, for example, digital cameras and smartphones the electronic device can be used.

In the field of traffic, the electronic device can be used in devices applied to traffic, such as an in-vehicle sensor that captures images of the front, rear, surroundings, inside, and the like of a vehicle, a monitoring camera that monitors traveling vehicles and roads, and a distance measuring sensor that measures the distance between vehicles and the like, for safe driving such as automatic stop, recognition of a driver's conditions, and the like.

In the field of home appliances, the electronic device can be used in devices applied to home appliances such as a television receiver, a refrigerator, and an air conditioner, for example, in order to capture images of a user's gesture and operate the device in response to the gesture.

In the field of medical treatment and health care, the electronic device can be used in devices applied to medical treatment and health care such as an endoscope and a device that performs angiography by receiving infrared light, for example.

In the field of security, the electronic device can be used in devices applied to security such as a surveillance camera for crime prevention and a camera for person authentication, for example.

In the field of beauty, the electronic device can be used in devices applied to beauty, such as a skin measuring instrument capturing images of the skin and a microscope capturing images of the scalp, for example.

In the field of sports, the electronic device can be used in devices applied to sports, such as an action camera and a wearable camera for sports applications, for example.

In the field of agriculture, the electronic device can be used in devices applied to agriculture, such as a camera for monitoring the conditions of fields and crops, for example.

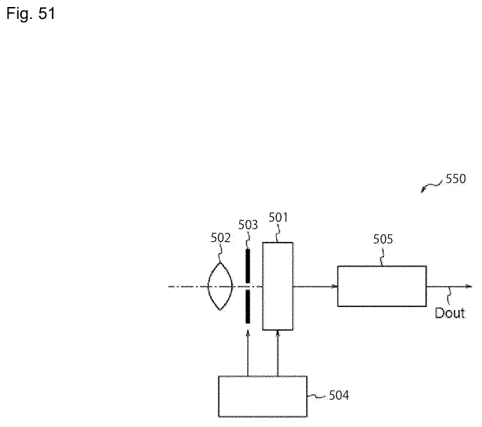

Next, examples of use of the electronic device will be specifically described. For example, as an electronic device that has a solid-state imaging device 501 composed of or including the semiconductor device according to each example, the electronic device can be applied to various types of electronic devices having an imaging function, such as a camera system such as a digital still camera or a video camera, or a mobile phone having an imaging function. FIG. 51 shows a schematic configuration of an electronic device 550 (camera) as an example of the abovementioned electronic device. The electronic device 550 is, for example, a video camera capable of capturing still images or moving images, and includes the solid-state imaging device 501, an optical system (optical lens) 502, a shutter device 503, a drive unit 504 that drives the solid-state imaging device 501 and the shutter device 503, and a signal processing unit 505.

The optical system 502 guides image light (incident light) from a subject to a pixel region of the solid-state imaging device 501. This optical system 502 may be constituted by a plurality of optical lenses. The shutter device 503 controls a light irradiation period and a light shielding period for the solid-state imaging device 501. The drive unit 504 controls a transfer operation of the solid-state imaging device 501 and a shutter operation of the shutter device 503. The signal processing unit 505 performs various types of signal processing on signals output from the solid-state imaging device 501. A video signal Dout obtained after signal processing is stored in a storage medium such as a memory or is output to a monitor or the like.

### 28. Another Example of Use of the Electronic Device Provided With the Semiconductor Device According to the Present Technology

An electronic device having the semiconductor device according to each example of an embodiment according to the present technology and including a solid-state imaging device (image sensor device) can be applied to other electronic devices for detecting light, such as a TOF (Time Of Flight) sensor. When applying to the TOF sensor, the electronic device can be applied to, for example, a distance image sensor using a direct TOF measurement method and a distance image sensor using an indirect TOF measurement method. In the distance image sensor using a direct TOF measurement method, since the timing at which photons arrive is obtained directly in a time domain in each pixel, a light pulse with a short pulse width is transmitted and an electrical pulse is generated by a receiver responding at high speed. The present disclosure can be applied to the receiver in this case. In addition, in the indirect TOF method, the detection and accumulation of carriers generated by light measure the flight time of the light by using a semiconductor element structure that changes depending on the timing of arrival of the light. The present disclosure can also be applied as such semiconductor structure. When applying to the TOF sensor, a color filter array and a microlens array may or may not be provided.

### 29. Example of Application to a Mobile Object

The technology according to the present disclosure (the present technology) can be applied to various products. For example, the technology according to the present disclosure may be realized as a device equipped in any type of mobile object such as an automobile, an electric vehicle, a hybrid electric vehicle, a motorcycle, a bicycle, a personal mobility device, an airplane, a drone, a ship, and a robot.

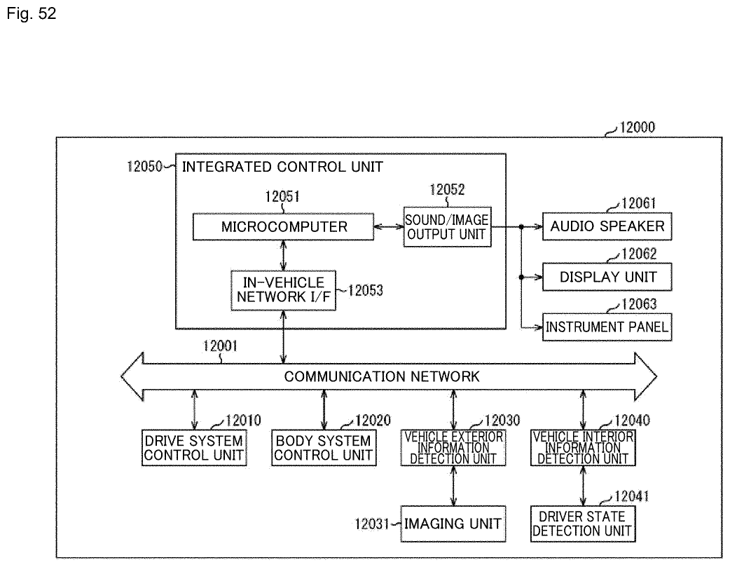

FIG. 52 is a block diagram showing an example of a schematic configuration of a vehicle control system, which is an example of a mobile object control system to which the technology according to the present disclosure can be applied.

A vehicle control system 12000 includes a plurality of electronic control units connected thereto via a communication network 12001. In the example shown in FIG. 52, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound/image output unit 12052, and an in-vehicle network interface I/F (interface) 12053 are illustrated.

The drive system control unit 12010 controls an operation of a device related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control device such as a braking device that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for people, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects the state of the driver is connected to the vehicle interior information detection unit 12040. The driver state detection unit 12041 includes, for example, a camera that captures an image of the driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generator, the steering mechanism, or the braking device on the basis of the information on the outside or the inside of the vehicle acquired by the vehicle exterior information detection unit 12030 or the vehicle interior information detection unit 12040 and output a control command to the drive system control unit 12010. For example, the microcomputer 12051 can perform cooperative control for the purpose of realizing functions of an ADAS (Advanced Driver Assistance System) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the vehicle exterior information acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound/image output unit 12052 transmits an output signal of at least one of sound and an image to an output device capable of visually or audibly notifying a passenger or the outside of the vehicle of information. In the example of FIG. 52, an audio speaker 12061, a display unit 12062, and an instrument panel 12063 are illustrated as examples of the output device. The display unit 12062 may include at least one of an on-board display and a head-up display, for example.

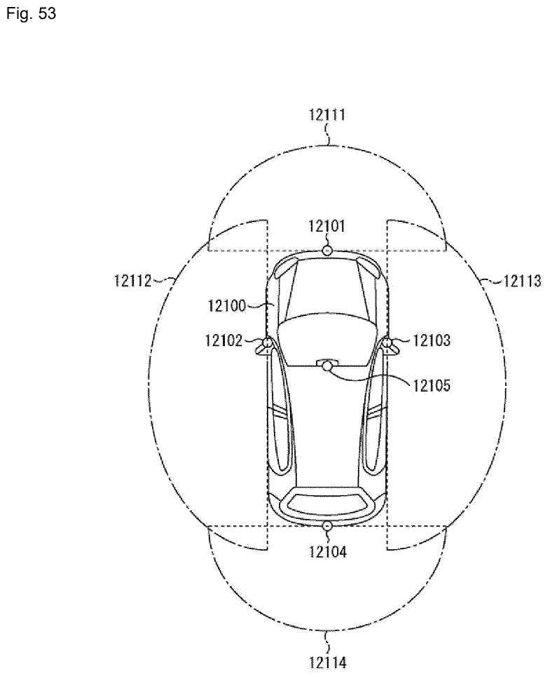

FIG. 53 is a diagram showing an example of an installation position of the imaging unit 12031.

In FIG. 53, a vehicle 12100 includes imaging units 12101, 12102, 12103, 12104, and 12105 as the imaging unit 12031.

The imaging units 12101, 12102, 12103, 12104, and 12105 are provided at positions such as a front nose, side-view mirrors, a rear bumper, a back door, and an upper portion of a windshield in a vehicle interior of the vehicle 12100, for example. The imaging unit 12101 provided on the front nose and the imaging unit 12105 provided in the upper portion of the windshield in the vehicle interior mainly acquire images of the front of the vehicle 12100. The imaging units 12102 and 12103 provided on the side-view mirrors mainly acquire images of a lateral side of the vehicle 12100. The imaging unit 12104 provided on the rear bumper or the back door mainly acquires images of the rear of the vehicle 12100. Front view images acquired by the imaging units 12101 and 12105 are mainly used for detection of preceding vehicles, pedestrians, obstacles, traffic lights, traffic signs, lanes, and the like.

FIG. 53 shows an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, a bird's-eye view image viewed from above the vehicle 12100 can be obtained.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path along which the vehicle 12100 is traveling, which is a three-dimensional object traveling at a predetermined speed (for example, 0 km/h or higher) in the substantially same direction as the vehicle 12100, as a vehicle ahead by acquiring a distance to each three-dimensional object in the imaging ranges 12111 to 12114 and a temporal change of the distance (a relative speed with respect to the vehicle 12100) on the basis of the distance information obtained from the imaging units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on the operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, the microcomputer 12051 can issue an alarm to the driver through the audio speaker 12061 or the display unit 12062, perform forced deceleration or avoidance steering through the drive system control unit 12010, and thus perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 functioning as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the sound/image output unit 12052 controls the display unit 12062 so that a square contour line for emphasis is superimposed and displayed with the recognized pedestrian. In addition, the sound/image output unit 12052 may control the display unit 12062 so that an icon indicating a pedestrian or the like is displayed at a desired position.

An example of the vehicle control system to which the technology according to the present disclosure (the present technology) can be applied has been described above. The technology according to the present disclosure may be applied, for example, to the imaging unit 12031 or the like among the configurations described above. Specifically, the solid-state imaging device 111 of the present disclosure can be applied to the imaging unit 12031. By applying the technology according to the present disclosure to the imaging unit 12031, throughput yield can be improved and the cost of production can be reduced.

### 30. Example of Application to an Endoscopic Surgery System

The present technology can be applied to various products. For example, the technology according to the present disclosure (the present technology) may be applied to an endoscopic surgery system.

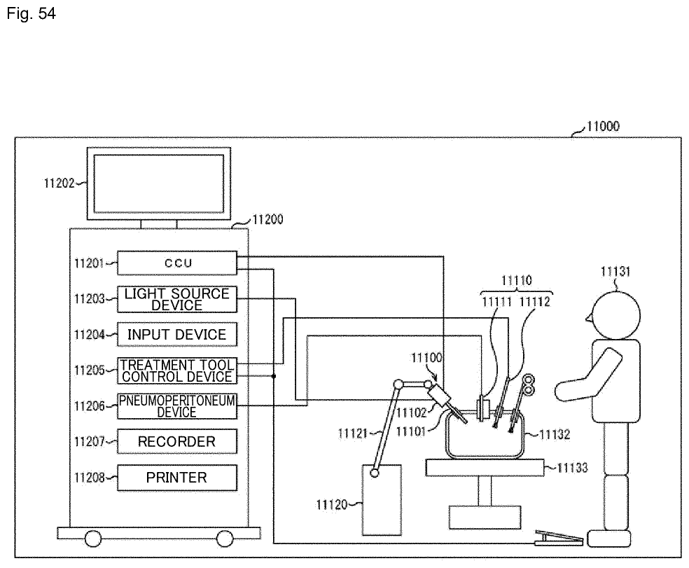

FIG. 54 is a diagram showing an example of a schematic configuration of an endoscope surgery system to which the technology according to the present disclosure (the present technology) is applied.

FIG. 54 shows a state where an operator (doctor) 11131 uses an endoscopic surgery system 11000 to perform a surgical operation on a patient 11132 on a patient bed 11133. As illustrated, the endoscopic surgery system 11000 is constituted of an endoscope 11100, another surgical instrument 11110 such as a pneumoperitoneum tube 11111 or an energized treatment tool 11112, a support arm device 11120 that supports the endoscope 11100, and a cart 11200 mounted with various devices for endoscopic surgery.

The endoscope 11100 includes a lens barrel 11101 of which a region having a predetermined length from a tip thereof is inserted into a body cavity of the patient 11132, and a camera head 11102 connected to a base end of the lens barrel 11101. In the illustrated example, the endoscope 11100 configured as a so-called rigid endoscope having the rigid lens barrel 11101 is illustrated, but the endoscope 11100 may be configured as a so-called flexible endoscope having a flexible lens barrel.

The tip end of the lens barrel 11101 is provided with an opening into which an objective lens is fitted. A light source device 11203 is connected to the endoscope 11100, light generated by the light source device 11203 is guided to the tip end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102, and the reflected light (observation light) from the observation target converges on the imaging element by the optical system. The observation light is photoelectrically converted by the imaging element, and an electrical signal corresponding to the observation light, that is, an image signal corresponding to an observation image, is generated. The image signal is transmitted to a camera control unit (CCU) 11201 as RAW data.

The CCU 11201 is constituted by a CPU (Central Processing Unit), a GPU (Graphics Processing Unit), and the like, and comprehensively controls the operations of the endoscope 11100 and a display device 11202. In addition, the CCU 11201 receives an image signal from the camera head 11102 and performs various types of image processing for displaying an image based on the image signal, such as development processing (de-mosaic processing) on the image signal.

The display device 11202 displays the image based on the image signal subjected to the image processing by the CCU 11201 under the control of the CCU 11201.

The light source device 11203 is constituted of, for example, a light source such as an LED (Light Emitting Diode) and supplies the endoscope 11100 with irradiation light when photographing a surgical site or the like.

An input device 11204 is an input interface for the endoscopic surgery system 11000. The user can input various types of information or instructions to the endoscopic surgery system 11000 via the input device 11204. For example, the user inputs an instruction to change imaging conditions (a type of radiation light, a magnification, a focal length, or the like) of the endoscope 11100.

The treatment tool control device 11205 controls driving of the energized treatment tool 11112 for cauterization or incision of a tissue, sealing of blood vessel, or the like. The pneumoperitoneum device 11206 sends a gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203 that supplies the endoscope 11100 with the radiation light for imaging the surgical site can be configured of, for example, an LED, a laser light source, or a white light source configured of a combination thereof. When a white light source is formed by a combination of RGB laser light sources, it is possible to control an output intensity and an output timing of each color (each wavelength) with high accuracy, and thus the light source device 11203 can adjust the white balance of the captured image. Further, in this case, laser light from each of the respective RGB laser light sources is radiated to the observation target in a time division manner, and driving of the imaging element of the camera head 11102 is controlled in synchronization with radiation timing such that images corresponding to respective RGB can be captured in a time division manner.

According to this method, it is possible to obtain a color image without providing a color filter in the imaging element.

Further, driving of the light source device 11203 may be controlled so that an intensity of output light is changed at predetermined time intervals. The driving of the imaging element of the camera head 11102 is controlled in synchronization with a timing of changing the intensity of the light, and images are acquired in a time division manner and combined, so that an image having a high dynamic range without so-called blackout and whiteout can be generated.

In addition, the light source device 11203 may have a configuration in which light in a predetermined wavelength band corresponding to special light observation can be supplied. In the special light observation, for example, by emitting light in a band narrower than that of radiation light (that is, white light) during normal observation using wavelength dependence of light absorption in a body tissue, so-called narrow band light observation (narrow band imaging) in which a predetermined tissue such as a blood vessel in a mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue, to obtain a fluorescence image. The light source device 11203 may have a configuration in which narrow band light and/or excitation light corresponding to such special light observation can be supplied.

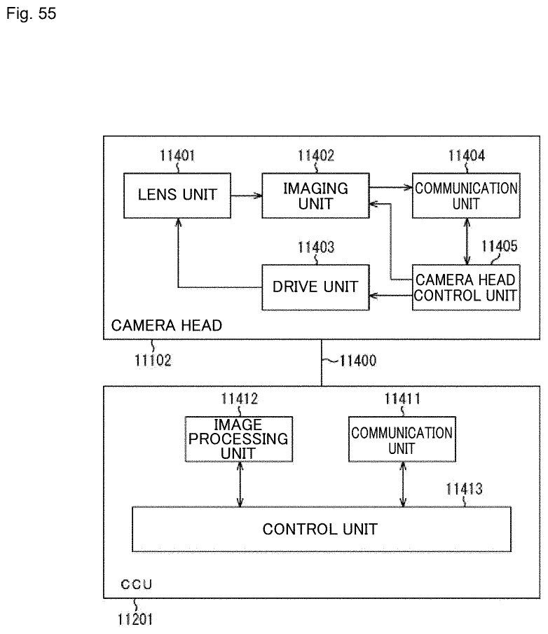

FIG. 55 is a block diagram showing an example of functional configurations of the camera head 11102 and the CCU 11201 shown in FIG. 54.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light taken from a tip of the lens barrel 11101 is guided to the camera head 11102 and is incident on the lens unit 11401. The lens unit 11401 is configured in combination of a plurality of lenses including a zoom lens and a focus lens.

The imaging unit 11402 is constituted by an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to respective RGB are generated by the imaging elements, and a color image may be obtained by synthesizing the image signals. Alternatively, the imaging unit 11402 may be configured to include a pair of imaging elements for acquiring each of image signals for the right eye and the left eye corresponding to three-dimensional (3D) display. When 3D display is performed, the operator 11131 can ascertain the depth of biological tissues in the surgical site more accurately. When the imaging unit 11402 is configured in a multi-plate type, a plurality of systems of lens units 11401 may be provided in correspondence to the imaging elements.

The imaging unit 11402 does not necessarily need to be provided in the camera head 11102. For example, the imaging unit 11402 may be provided immediately after the objective lens inside the lens barrel 11101.

The drive unit 11403 is configured by an actuator, and the zoom lens and the focus lens of the lens unit 11401 are moved by a predetermined distance along an optical axis under the control of the camera head control unit 11405. Accordingly, the magnification and focus of the image captured by the imaging unit 11402 can be adjusted appropriately.

The communication unit 11404 is configured using a communication device for transmitting and receiving various types of information to and from the CCU 11201. The communication unit 11404 transmits the image signal obtained from the imaging unit 11402 as RAW data to the CCU 11201 via the transmission cable 11400.

The communication unit 11404 receives a control signal for controlling driving of the camera head 11102 from the CCU 11201 and supplies the camera head control unit 11405 with the control signal. The control signal includes, for example, information regarding imaging conditions, such as information indicating designation of a frame rate of a captured image, information indicating designation of an exposure value at the time of imaging, and/or information indicating designation of a magnification and a focus of the captured image.

The imaging conditions such as the frame rate, the exposure value, the magnification, and the focus may be appropriately designated by the user, or may be automatically set by the control unit 11413 of the CCU 11201 on the basis of the acquired image signal. In the latter case, a so-called AE (Auto Exposure) function, a so-called AF (Auto Focus) function, and a so-called AWB (Auto White Balance) function are provided in the endoscope 11100.

The camera head control unit 11405 controls driving of the camera head 11102 on the basis of a control signal from the CCU 11201 received via the communication unit 11404.

The communication unit 11411 is constituted of a communication device that transmits and receives various types of information to and from the camera head 11102. The communication unit 11411 receives an image signal transmitted via the transmission cable 11400 from the camera head 11102.

Further, the communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various types of control on imaging of a surgical site by the endoscope 11100, and display of a captured image obtained through imaging of a surgical site, or the like. For example, the control unit 11413 generates a control signal for controlling driving of the camera head 11102.

In addition, the control unit 11413 causes the display device 11202 to display a captured image showing a surgical site or the like based on an image signal subjected to the image processing by the image processing unit 11412. In doing so, the control unit 11413 may recognize various objects in the captured image using various image recognition techniques. For example, the control unit 11413 can recognize a surgical instrument such as forceps, a specific biological site, bleeding, mist or the like at the time of use of the energized treatment tool 11112, or the like by detecting a shape, a color, or the like of an edge of an object included in the captured image. When the display device 11202 is caused to display a captured image, the control unit 11413 may superimpose various types of surgery support information on an image of the surgical site for display by using a recognition result of the captured image. By displaying the surgery support information in a superimposed manner and presenting it to the operator 11131, a burden on the operator 11131 can be reduced, and the operator 11131 can surely proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

An example of an endoscopic surgery system to which the technology according to the present disclosure can be applied has been described above. The technology according to the present disclosure can be applied to the endoscope 11100, the camera head 11102 (the imaging unit 11402 thereof), and the like among the configurations described above. Specifically, the solid-state imaging device 111 according to the present disclosure can be applied to the imaging unit 10402. By applying the technology according to the present disclosure to the endoscope 11100, the camera head 11102 (the imaging unit 11402 thereof), and the like, throughput yield can be improved and the cost of production can be reduced.

While the endoscopic surgery system has been described here as an example, the technology according to the present disclosure may be applied to other systems such as a microscopic surgery system.

In addition, the present technology can also have the following configurations.

(1) A semiconductor device, comprising:
at least one first element substrate;
at least one second element substrate laminated with the first element substrate and smaller than the first element substrate; and
a filling layer filling in at least a periphery of the second element substrate,
wherein at least a part of an end portion of the second element substrate on the first element substrate side is a thermal expansion suppression portion, and/or the thermal expansion suppression portion is provided directly or indirectly on an end surface of the part.

(2) The semiconductor device according to (1), wherein the first element substrate includes a first semiconductor substrate and a first wiring layer laminated together, the second element substrate includes a second semiconductor substrate and a second wiring layer laminated together, and the first and second element substrates are bonded to each other in such a manner that the first and second wiring layers face each other.

(3) The semiconductor device according to (2), wherein the thermal expansion suppression portion is provided directly or indirectly at least on an end surface of the second wiring layer out of end surfaces of the second semiconductor substrate and the second wiring layer.

(4) The semiconductor device according to (2) or (3), wherein the thermal expansion suppression portion has a lower thermal expansion coefficient than the second wiring layer.

(5) The semiconductor device according to any one of (2) to (4), wherein the thermal expansion suppression portion has a lower thermal expansion coefficient than the second semiconductor substrate.

(6) The semiconductor device according to any one of (2) to (5), wherein the second semiconductor substrate is a silicon substrate.

(7) The semiconductor device according to any one of (2) to (6), wherein the thermal expansion suppression portion is made of an inorganic material or an organic material.

(8) The semiconductor device according to any one of (2) to (7), wherein the thermal expansion suppression portion has rounded corners.

(9) The semiconductor device according to any one of (2) to (8), wherein the thermal expansion suppression portion is at least a part of an end portion of the second wiring layer on the first element substrate side.

(10) The semiconductor device according to (9), wherein the thermal expansion suppression portion has a lower percentage of metal than a part of the second wiring layer other than the thermal expansion suppression portion.

(11) The semiconductor device according to (9) or (10), wherein the percentage of metal in the thermal expansion suppression portion is 10% or less.

(12) The semiconductor device according to any one of (9) to (11), wherein a width of the thermal expansion suppression portion in an in-plane direction is 100 μm or more.

(13) The semiconductor device according to any one of (9) to (12), wherein the thermal expansion suppression portion has a plurality of parts that are arranged in the in-plane direction and have different percentages of metal.

(14) The semiconductor device according to any one of (9) to (13), wherein the thermal expansion suppression portion has a plurality of parts that are arranged in a lamination direction and have different percentages of metal.

(15) The semiconductor device according to any one of (9) to (14), wherein the metal includes any of Cu, Al, W, Au, Co, Ta, and Ti.

(16) The semiconductor device according to any one of (1) to (15), further comprising a protective film provided between the filling layer and a set of the first wiring layer, the second wiring layer, and the second semiconductor substrate.

(17) The semiconductor device according to (16), wherein the protective film is made of SiN.

(18) The semiconductor device according to any one of (1) to (17), wherein the filling layer is made of an inorganic oxide film or an organic film.

(19) The semiconductor device according to any one of (1) to (18), further comprising a heat dissipation member bonded to a surface of the filling layer that is opposite to the first element side.

(20) The semiconductor device according to (19), wherein the heat dissipation member includes any of SiC, AIN, SiN, Cu, Al, and C.

(21) The semiconductor device according to any one of (1) to (20), further comprising a support substrate provided on a side of the filling layer that is opposite to the first element substrate side.

(22) The semiconductor device according to (21), wherein the filling layer and the support substrate are bonded to each other.

(23) The semiconductor device according to any one of (1) to (22), wherein the at least one second element substrate is a plurality of the second element substrates.

(24) The semiconductor device according to (23), wherein the plurality of second element substrates include at least two of the second element substrates arranged in an in-plane direction.

(25) The semiconductor device according to (23) or (24), wherein the plurality of second element substrates include at least two of the second element substrates laminated.

(26) The semiconductor device according to any one of (1) to (25), wherein the at least one first element substrate is a plurality of the first element substrates laminated.

(27) The semiconductor device according to any one of (1) to (26), wherein the first element substrate includes a pixel portion having a photoelectric conversion element, and the second element substrate processes a signal output from the pixel portion.

(28) The semiconductor device according to any one of (1) to (27), wherein the second element substrate includes any of a memory element, a logic element, an analog element, an interface element, and an AI element.

(29) An electronic device, comprising the semiconductor device according to any one of (1) to (28).

(30) A method for manufacturing a semiconductor device, comprising the steps of:
bonding a first element substrate in which a first semiconductor substrate and a first wiring layer are laminated, and a second element substrate in which a second semiconductor substrate and a second wiring layer are laminated and which is smaller than the first element substrate, in such a manner that the first and second wiring layers face each other;
forming a thermal expansion suppression film directly or indirectly on the first and second element substrates;
removing a part of the thermal expansion suppression film other than a part provided directly or indirectly on an end surface of the second element substrate; and
filling a periphery of the second element substrate with a filling film, the second element substrate having the thermal expansion suppression film provided directly or indirectly on the end surface of the second element substrate.

(31) The method for manufacturing a semiconductor device according to (30), comprising the step of forming a protective film on the first and second element substrate between the step of bonding the first element substrate and the second element substrate and the step of forming the thermal expansion suppression film.

(32) The method for manufacturing a semiconductor device according to (31), further comprising the step of making the filling film flat and the step of bonding the filling film, which is flattened, and a heat dissipation member.

(33) The method for manufacturing a semiconductor device according to (31), further comprising the step of making the filling film flat and the step of bonding the filling film, which is flattened, and a support member.

### REFERENCE SIGNS LIST

10, 20, 30, 40, 50, 60, 70, 80, 90, 100, 110, 120, 130, 140, 150, 160, 170, 180, 190,
200, 210, 220, 230, 240, 250 Semiconductor device
101 First element substrate
101a First semiconductor substrate
101b First wiring layer
201 Second element substrate
201a Second semiconductor substrate
201b Second wiring layer
300 Protective film
201b2, 400 Thermal expansion suppression portion
500 Filling layer
550 Electronic device
600 Support substrate
700 Color filter
800 On-chip lens
1500, 1600 Multi-layer film (heat dissipation member)

1. A semiconductor device, comprising:
at least one first element substrate;
at least one second element substrate laminated with the first element substrate and smaller than the first element substrate; and
a filling layer filling in at least a periphery of the second element substrate,
wherein at least a part of an end portion of the second element substrate on the first element substrate side is a thermal expansion suppression portion, and/or the thermal expansion suppression portion is provided directly or indirectly on an end surface of the part.

2. The semiconductor device according to claim 1, wherein the first element substrate includes a first semiconductor substrate and a first wiring layer laminated together, the second element substrate includes a second semiconductor substrate and a second wiring layer laminated together, and
the first and second element substrates are bonded to each other in such a manner that the first and second wiring layers face each other.

3. The semiconductor device according to claim 2, wherein the thermal expansion suppression portion is provided directly or indirectly at least on an end surface of the second wiring layer out of end surfaces of the second semiconductor substrate and the second wiring layer.

4. The semiconductor device according to claim 3, wherein the thermal expansion suppression portion has a lower thermal expansion coefficient than the second wiring layer.

5. The semiconductor device according to claim 3, wherein the thermal expansion suppression portion has a lower thermal expansion coefficient than the second semiconductor substrate.

6. The semiconductor device according to claim 5,
wherein the second semiconductor substrate is a silicon substrate.

7. The semiconductor device according to claim 3, wherein the thermal expansion suppression portion is made of an inorganic material or an organic material.

8. The semiconductor device according to claim 3, wherein the thermal expansion suppression portion has rounded corners.

9. The semiconductor device according to claim 2, wherein the thermal expansion suppression portion is at least a part of an end portion of the second wiring layer on the first element substrate side.

10. The semiconductor device according to claim 9, wherein a width of the thermal expansion suppression portion in an in-plane direction is 100 μm or more.

11. The semiconductor device according to claim 2, further comprising a protective film provided between the filling layer and a set of the first wiring layer, the second wiring layer, and the second semiconductor substrate.

12. The semiconductor device according to claim 11, wherein the protective film is made of SiN.

13. The semiconductor device according to claim 1, further comprising a heat dissipation member bonded to a surface of the filling layer that is opposite to the first element substrate side.

14. The semiconductor device according to claim 13, wherein the heat dissipation member includes any of SiC, AIN, SiN, Cu, Al, and C.

15. The semiconductor device according to claim 1, wherein the at least one second element substrate is a plurality of the second element substrates.

16. The semiconductor device according to claim 1, wherein the at least one first element substrate is a plurality of the first element substrates that are laminated.

17. The semiconductor device according to claim 1, wherein the first element substrate includes a pixel portion having a photoelectric conversion element, and the second element substrate processes a signal output from the pixel portion.

18. The semiconductor device according to claim 17, wherein the second element substrate includes any of a memory element, a logic element, an analog element, an interface element, and an AI element.

19. An electronic device, comprising the semiconductor device according to claim 1.
